(19) United States
(12) Patent Application Publication
(10) Pub. No.: US 2025/0098251 A1
(43) Pub. Date: Mar. 20, 2025

(54) SEMICONDUCTOR DEVICE, SEMICONDUCTOR DEVICE MANUFACTURING METHOD, INVERTER CIRCUIT, DRIVE DEVICE, VEHICLE, AND ELEVATOR

(71) Applicant: KABUSHIKI KAISHA TOSHIBA, Tokyo (JP)

(72) Inventor: Tatsuo SHIMIZU, Shinagawa (JP)

(73) Assignee: KABUSHIKI KAISHA TOSHIBA, Tokyo (JP)

(21) Appl. No.: 18/965,021

(22) Filed: Dec. 2, 2024

Related U.S. Application Data
(62) Division of application No. 17/447,006, filed on Sep. 7, 2021.

(30) Foreign Application Priority Data
Mar. 18, 2021 (JP) 2021-045128

(51) Int. Cl. H01L 29/16; H01L 29/36; H01L 29/66

(52) U.S. Cl. CPC H10D 62/8325; H10D 48/01; H10D 62/60

(57) ABSTRACT

A semiconductor device of embodiments includes: a silicon carbide layer having a first face having an off-angle of 0° or more and 8° or less with respect to a {0001} face and a second face opposite to the first face, having a 4H-SiC crystal structure, and including a first silicon carbide region of p-type, a second silicon carbide region of n-type between the first silicon carbide region and the first face, and a third silicon carbide region between the first silicon carbide region and the first face and containing oxygen, the second silicon carbide region disposed between the third silicon carbide region and the first face; a gate electrode; a silicon oxide layer between the silicon carbide layer and the gate electrode; and a region disposed between the silicon carbide layer and the silicon oxide layer and having a nitrogen concentration of 1×10²¹ cm⁻³ or more.

### CROSS-REFERENCE TO RELATED APPLICATION

This application is a divisional of and claims benefit under 35 U.S.C. § 120 to U.S. patent application Ser. No. 17/447,006, filed Sep. 7, 2021, and claims the benefit of priority under 35 U.S.C. § 119 from Japanese Patent Application No. 2021-045128, filed on Mar. 18, 2021, the entire contents of which are incorporated herein by reference.

### FIELD

Embodiments described herein relate generally to a semiconductor device, a semiconductor device manufacturing method, an inverter circuit, a drive device, a vehicle, and an elevator.

### BACKGROUND

Silicon carbide (SiC) is expected as a material for next-generation semiconductor devices. Silicon carbide has excellent physical properties, such as a bandgap of 3 times that of silicon (Si), a breakdown field strength of about 10 times that of silicon, and a thermal conductivity of about 3 times that of silicon. By using such characteristics, it is possible to realize a semiconductor device that can operate at high temperature with low loss.

For example, when a metal oxide semiconductor field effect transistor (MOSFET) is formed using silicon carbide, there is a risk that the reliability of the gate insulating layer will decrease or the mobility of carriers will decrease. The decrease in reliability of the gate insulating layer or the decrease in mobility of carriers is caused by, for example, the interface state between the silicon carbide layer and the gate insulating layer.

### BRIEF DESCRIPTION OF THE DRAWINGS

FIG. 1 is a schematic cross-sectional view of a semiconductor device of a first embodiment;

FIG. 2 is a diagram showing a crystal structure of a SiC semiconductor;

FIG. 3 is a diagram showing a crystal structure of a 4H-SiC semiconductor;

FIGS. 4A, 4B, and 4C are diagrams showing the surface structure of a 4H-SiC semiconductor;

FIGS. 5A, 5B, 5C, and 5D are explanatory diagrams of an oxygen region in the first embodiment;

FIG. 6 is a diagram showing the element concentration distribution of the semiconductor device of the first embodiment;

FIGS. 7A and 7B are schematic diagrams showing the bonding state of a nitrogen atom in the semiconductor device of the first embodiment;

FIG. 8 is an explanatory diagram of the surface structure of a silicon carbide layer of the semiconductor device of the first embodiment;

FIG. 9 is an explanatory diagram of the method for manufacturing the semiconductor device of the first embodiment;

FIG. 10 is an explanatory diagram of the method for manufacturing the semiconductor device of the first embodiment;

FIG. 11 is an explanatory diagram of the method for manufacturing the semiconductor device of the first embodiment;

FIG. 12 is an explanatory diagram of the method for manufacturing the semiconductor device of the first embodiment;

FIG. 13 is an explanatory diagram of the method for manufacturing the semiconductor device of the first embodiment;

FIG. 14 is an explanatory diagram of the method for manufacturing the semiconductor device of the first embodiment;

FIG. 15 is an explanatory diagram of the method for manufacturing the semiconductor device of the first embodiment;

FIG. 16 is an explanatory diagram of the method for manufacturing the semiconductor device of the first embodiment;

FIG. 17 is an explanatory diagram of the method for manufacturing the semiconductor device of the first embodiment;

FIG. 18 is an explanatory diagram of the method for manufacturing the semiconductor device of the first embodiment;

FIG. 19 is an explanatory diagram of the method for manufacturing the semiconductor device of the first embodiment;

FIG. 20 is an explanatory diagram of the method for manufacturing the semiconductor device of the first embodiment;

FIG. 21 is an explanatory diagram of the method for manufacturing the semiconductor device of the first embodiment;

FIG. 22 is an explanatory diagram of the method for manufacturing the semiconductor device of the first embodiment;

FIGS. 23A, 23B, and 23C are explanatory diagrams of the function and effect of the semiconductor device of the first embodiment;

FIG. 24 is an explanatory diagram of the function and effect of the semiconductor device of the first embodiment;

FIG. 25 is an explanatory diagram of the function and effect of the semiconductor device of the first embodiment;

FIG. 26 is an explanatory diagram of the function and effect of the semiconductor device of the first embodiment;

FIG. 27 is an explanatory diagram of the function and effect of the semiconductor device of the first embodiment;

FIG. 28 is a diagram showing the electron state of the semiconductor device of the first embodiment;

FIGS. 29A and 29B are explanatory diagrams of the function and effect of the semiconductor device of the first embodiment;

FIG. 30 is a schematic cross-sectional view of a semiconductor device of a second embodiment;

FIG. 31 is a schematic diagram of a drive device of a third embodiment;

FIG. 32 is a schematic diagram of a vehicle of a fourth embodiment;

FIG. 33 is a schematic diagram of a vehicle of a fifth embodiment; and

FIG. 34 is a schematic diagram of an elevator of a sixth embodiment.

### DETAILED DESCRIPTION

A semiconductor device of embodiments includes: a silicon carbide layer having a first face having an off-angle of 0° or more and 8° or less with respect to a {0001} face and a second face opposite to the first face, the silicon carbide layer having a 4H-SiC crystal structure, and the silicon carbide layer including a first silicon carbide region of p-type, a second silicon carbide region of n-type disposed between the first silicon carbide region and the first face, and a third silicon carbide region disposed between the first silicon carbide region and the first face and containing oxygen, the second silicon carbide region being disposed between the third silicon carbide region and the first face; a gate electrode; a silicon oxide layer disposed between the silicon carbide layer and the gate electrode; and a region disposed between the silicon carbide layer and the silicon oxide layer and having a nitrogen concentration of 1×10²¹ cm⁻³ or more.

Hereinafter, embodiments will be described with reference to the diagrams. In the following description, the same or similar members and the like are denoted by the same reference numerals, and the description of the members and the like once described may be omitted as appropriate.

In addition, in the following description, when there are notations of n⁺, n, n⁻, p⁺, p, and p⁻, these indicate the relative high and low of the impurity concentration in each conductive type. That is, n⁺ indicates that the n-type impurity concentration is relatively higher than n, and n-indicates that the n-type impurity concentration is relatively lower than n. In addition, p⁺ indicates that the p-type impurity concentration is relatively higher than p, and p-indicates that the p-type impurity concentration is relatively lower than p. In addition, n⁺-type and n⁻-type may be simply described as n-type, p⁺-type and p⁻-type may be simply described as p-type. Unless otherwise specified, the impurity concentration in each region is represented by, for example, the value of the impurity concentration in the central portion of each region.

The impurity concentration can be measured by, for example, secondary ion mass spectrometry (SIMS). In addition, the relative high and low of the impurity concentration can be determined from, for example, the high and low of the carrier concentration obtained by scanning capacitance microscopy (SCM). In addition, the distance such as the width or depth of an impurity region can be calculated from, for example, SIMS. In addition, the distance such as the width or depth of an impurity region can be calculated from, for example, an SCM image.

The thickness of an insulating layer and the like can be measured, for example, on the profile of SIMS or the image of a transmission electron microscope (TEM) or by a scanning electron microscope (SEM).

In addition, the bonding states of silicon atoms, carbon atoms, nitrogen atoms, and oxygen atoms in the silicon carbide layer can be identified by using, for example, X-ray photoelectron spectroscopy (XPS). In addition, the concentrations of various bonding states and the magnitude relationship between the concentrations can be determined by using, for example, X-ray photoelectron spectroscopy.

The bonding state of oxygen atoms in the silicon carbide layer can be identified by using X-ray photoelectron spectroscopy, infrared spectroscopy, or Raman spectroscopy. In addition, whether or not the oxygen atom in the silicon carbide layer is disposed at the carbon site of the crystal structure of silicon carbide can be determined by using, for example, X-ray photoelectron spectroscopy, infrared spectroscopy, or Raman spectroscopy. In addition, whether or not the oxygen atom in the silicon carbide layer is disposed at the silicon site of the crystal structure of silicon carbide can be determined by using, for example, X-ray photoelectron spectroscopy, infrared spectroscopy, or Raman spectroscopy.

The surface structure of the silicon carbide layer can be observed by using, for example, a TEM image. For example, the arrangement of atoms on the surface of the silicon carbide layer can be analyzed by using a TEM image. In addition, the surface structure of the silicon carbide layer can be analyzed by, for example, scanning tunneling spectroscopy (STS method).

### First Embodiment

A semiconductor device of a first embodiment includes: a silicon carbide layer having a first face having an off-angle of 0° or more and 8° or less with respect to a {0001} face and a second face opposite to the first face, the silicon carbide layer having a 4H-SiC crystal structure, and the silicon carbide layer including a first silicon carbide region of p-type, a second silicon carbide region of n-type disposed between the first silicon carbide region and the first face, and a third silicon carbide region disposed between the first silicon carbide region and the first face and containing oxygen, the second silicon carbide region being disposed between the third silicon carbide region and the first face; a gate electrode; a silicon oxide layer disposed between the silicon carbide layer and the gate electrode; and a region disposed between the silicon carbide layer and the silicon oxide layer and having a nitrogen concentration of 1×10²¹ cm⁻³ or more.

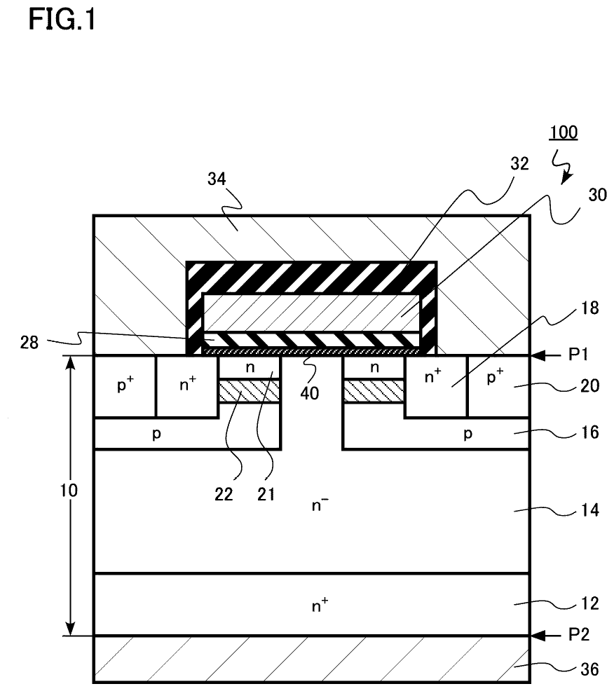

FIG. 1 is a schematic cross-sectional view of the semiconductor device of the first embodiment. The semiconductor device is a MOSFET 100. The MOSFET 100 is a double implantation MOSFET (DIMOSFET) in which a p-well and a source region are formed by ion implantation. In addition, the MOSFET 100 is an n-channel MOSFET having electrons as carriers.

The MOSFET 100 includes a silicon carbide layer 10, a gate insulating layer 28 (silicon oxide layer), a gate electrode 30, an interlayer insulating film 32, a source electrode 34, a drain electrode 36, and an interface termination region 40 (region).

The silicon carbide layer 10 includes a drain region 12, a drift region 14, a p-well region 16 (first silicon carbide region), a source region 18, a p-well contact region 20, an n-type region 21 (second silicon carbide region), and an oxygen region 22 (third silicon carbide region).

The gate insulating layer 28 is an example of the silicon oxide layer. The interface termination region 40 is an example of the region. The p-well region 16 is an example of the first silicon carbide region. The n-type region 21 is an example of the second silicon carbide region. The oxygen region 22 is an example of the third silicon carbide region.

The silicon carbide layer 10 is a single crystal SiC semiconductor. The silicon carbide layer 10 has a first face P1 and a second face P2 opposite to the first face P1. Hereinafter, the first face P1 may be referred to as a surface of the silicon carbide layer 10, and the second face P2 may be referred to as a back surface of the silicon carbide layer 10.

In this specification, the “depth” means a depth with respect to the first face P1.

The silicon carbide layer 10 is disposed between the source electrode 34 and the drain electrode 36. The source electrode 34 is provided on the first face P1 side of the silicon carbide layer 10. The drain electrode 36 is provided on the second face P2 side of the silicon carbide layer 10.

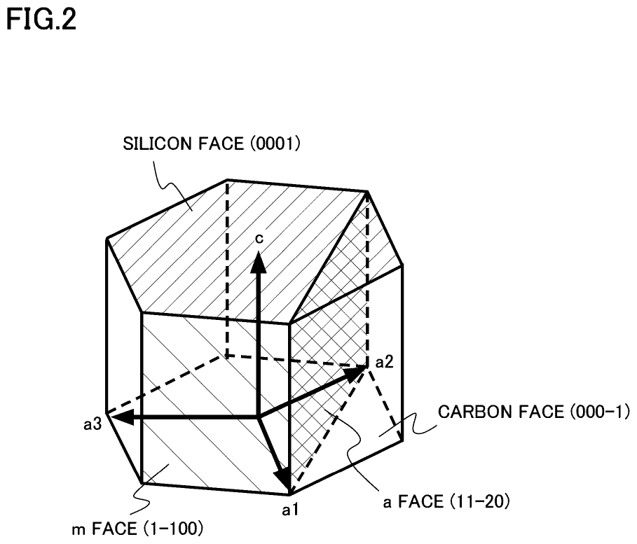

FIG. 2 is a diagram showing the crystal structure of a SiC semiconductor. A typical crystal structure of the SiC semiconductor is a hexagonal crystal system such as 4H-SiC. One of the faces (top faces of the hexagonal column) whose normal line is a c-axis along the axial direction of the hexagonal column is a (0001) face. The face equivalent to the (0001) face is referred to as a silicon face (Si face) and denoted as a {0001} face. Silicon atoms (Si) are arranged on the outermost surface of the silicon face.

The other side of the face (top face of the hexagonal column) whose normal line is the c-axis along the axial direction of the hexagonal column is a (000-1) face. The face equivalent to the (000-1) face is referred to as a carbon face (C face) and denoted as a {000-1} face. Carbon atoms (C) are arranged on the outermost surface of the carbon face.

The side face (pillar face) of the hexagonal column is an m face that is a face equivalent to the (1-100) face, that is, a {1-100} face. In addition, the face passing through a pair of ridge lines not adjacent to each other is an a face that is a face equivalent to the (11-20) face, that is, a {11-20} face. Both silicon atoms (Si) and carbon atoms (C) are arranged on the outermost surfaces of the m face and the a face.

The silicon carbide layer 10 has a 4H-SiC crystal structure. The first face P1 of the silicon carbide layer 10 has an off-angle of 0° or more and 8° or less with respect to the {0001} face. The first face P1 is a face inclined by an angle of 0° or more and 8° or less with respect to the silicon face, and the second face P2 is a face inclined by an angle of 0° or more and 8° or less with respect to the carbon face.

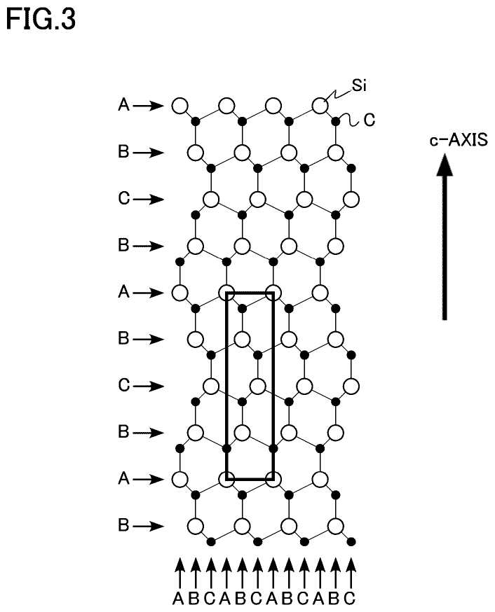

FIG. 3 is a diagram showing a crystal structure of a 4H-SiC semiconductor. FIG. 3 shows the arrangement of silicon atoms and carbon atoms of a 4H-SiC semiconductor.

In FIG. 3, silicon atoms are expressed by white circles and carbon atoms are expressed by black circles. The region surrounded by a square is a 4H-SiC unit cell. The 4H-SiC is configured by repeatedly arranging the unit cells.

The 4H-SiC contains four silicon atomic layers in one cycle in the stacking direction (c-axis direction). As the site position occupied by the silicon atom, there are three site positions. The three site positions are A site, B site, and C site.

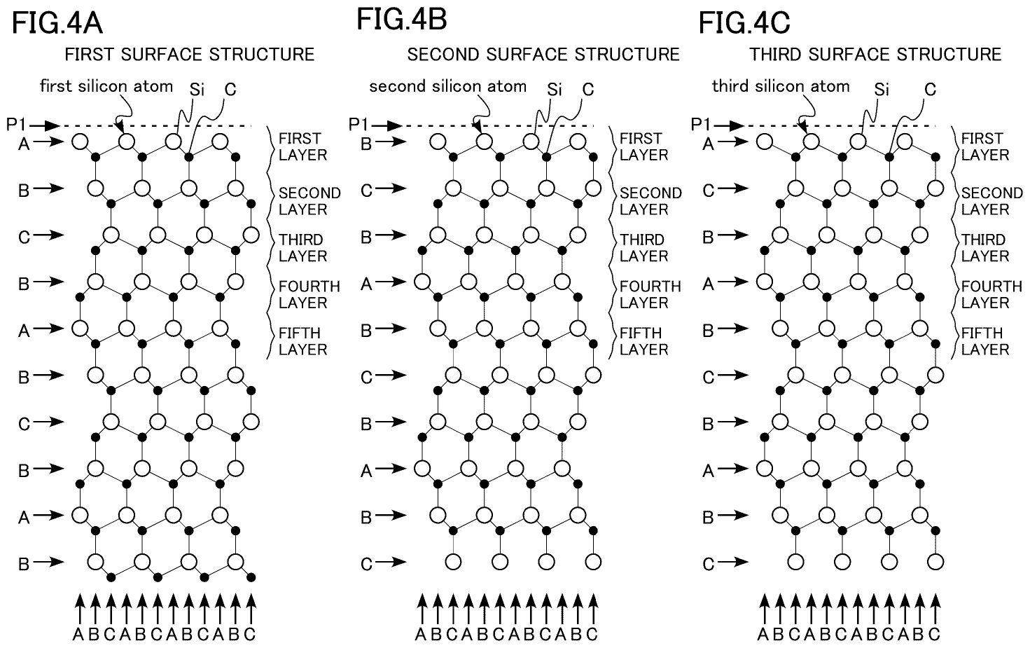

FIGS. 4A, 4B, and 4C are diagrams showing the surface structure of a 4H-SiC semiconductor. FIGS. 4A, 4B, and 4C are explanatory diagrams of a surface structure that can be formed on the surface of the 4H-SiC semiconductor. FIGS. 4A, 4B, and 4C are explanatory diagrams of the surface structure that can be formed on the first face P1 side of the silicon carbide layer 10. FIG. 4A shows a first surface structure, FIG. 4B shows a second surface structure, and FIG. 4C shows a third surface structure. Each of the first to fifth layers shown in FIGS. 4A, 4B, and 4C includes an upper silicon atomic layer and a lower carbon atomic layer. The first layer, the second layer, the third layer, the fourth layer, and the fifth layer disposed from the first face P1 towards the second face P2 in this order. The first layer is an uppermost layer in the silicon carbide layer 10 and in contact with the first face P1.

The silicon atom disposed in the first layer of the outermost surface of the first surface structure shown in FIG. 4A is the first silicon atom. The site position occupied by the first silicon atom is different from the site position occupied by a silicon atom in the third layer below the first silicon atom, and is the same as the site position occupied by the silicon atom in the fifth layer below the first silicon atom.

In the first surface structure, the site position occupied by the first silicon atom disposed in the first layer is the A site. The site position occupied by the silicon atom in the third layer is the C site. The site position occupied by the silicon atom in the fifth layer is the A site. Therefore, the site position occupied by the first silicon atom is different from the site position occupied by the silicon atom in the third layer, and is the same as the site position occupied by the silicon atom in the fifth layer.

The silicon atom disposed in the first layer of the outermost surface of the second surface structure shown in FIG. 4B is the second silicon atom. The site position occupied by the second silicon atom is the same as the site position occupied by a silicon atom in the third layer below the second silicon atom, and is the same as the site position occupied by the silicon atom in the fifth layer below the second silicon atom.

In the second surface structure, the site position occupied by the second silicon atom disposed in the first layer of the outermost surface is the B site. The site position occupied by the silicon atom in the third layer is the B site. The site position occupied by the silicon atom in the fifth layer is the B site. Therefore, the site position occupied by the second silicon atom is the same as the site position occupied by the silicon atom in the third layer, and is the same as the site position occupied by the silicon atom in the fifth layer.

The silicon atom disposed in the first layer of the outermost surface of the third surface structure shown in FIG. 4C is the third silicon atom. The site position occupied by the third silicon atom is different from the site position occupied by a silicon atom in the third layer below the third silicon atom, and is also different from the site position occupied by the silicon atom in the fifth layer below the third silicon atom.

In the third surface structure, the site position occupied by the third silicon atom disposed in the first layer of the outermost surface is the A site. The site position occupied by the silicon atom in the third layer is the B site. The site position occupied by the silicon atom in the fifth layer is the B site. Therefore, the site position occupied by the third silicon atom is different from the site position occupied by the silicon atom in the third layer, and is also different from the site position occupied by the silicon atom in the fifth layer. In the third surface structure, the periodicity of the first layer of the outermost surface is broken.

The drain region 12 is an n⁺-type SiC. The drain region 12 contains, for example, nitrogen (N) as an n-type impurity. The n-type impurity concentration in the drain region 12 is, for example, equal to or more than 1×10¹⁸ cm⁻³ and equal to or less than 1×10²¹ cm⁻³.

The drift region 14 is provided on the drain region 12. The drift region 14 is an n⁻-type SiC. The drift region 14 contains, for example, nitrogen as an n-type impurity.

The n-type impurity concentration in the drift region 14 is lower than the n-type impurity concentration in the drain region 12. The n-type impurity concentration in the drift region 14 is, for example, equal to or more than 1×10¹⁵ cm⁻³ and equal to or less than 2×10¹⁶ cm⁻³. The drift region 14 is, for example, a Sic epitaxial growth layer formed on the drain region 12 by an epitaxial growth method.

The thickness of the drift region 14 is, for example, equal to or more than 5 μm and equal to or less than 100 μm.

The p-well region 16 is provided between the drift region 14 and the first face P1. The p-well region 16 is disposed between the drift region 14 and the gate insulating layer 28. The p-well region 16 is a p-type SiC.

The p-well region 16 contains, for example, aluminum (Al) as a p-type impurity. The p-type impurity concentration in the p-well region 16 is, for example, equal to or more than 1×10¹⁶ cm⁻³ and equal to or less than 1×10²⁰ cm⁻³.

The depth of the p-well region 16 is, for example, equal to or more than 0.4 μm and equal to or less than 0.8 μm. The p-well region 16 functions as a channel region of the MOSFET 100.

The source region 18 is provided between the p-well region 16 and the first face P1. The source region 18 is, an n⁺-type SiC. The source region 18 contains, for example, phosphorus (P) as an n-type impurity. The n-type impurity concentration in the source region 18 is, for example, equal to or more than 1×10¹⁸ cm⁻³ and equal to or less than 1×10²² cm⁻³.

The depth of the source region 18 is smaller than the depth of the p-well region 16. The depth of the source region 18 is, for example, equal to or more than 0.2 μm and equal to or less than 0.4 μm.

The p-well contact region 20 is provided between the p-well region 16 and the first face P1. The p-well contact region 20 is provided on the side of the source region 18. The p-well contact region 20 is a p⁺-type SiC.

The p-well contact region 20 contains, for example, aluminum as a p-type impurity. The p-type impurity concentration in the p-well contact region 20 is, for example, equal to or more than 1×10¹⁸ cm⁻³ and equal to or less than 1×10²² cm⁻³.

The depth of the p-well contact region 20 is smaller than the depth of the p-well region 16. The depth of the p-well contact region 20 is, for example, equal to or more than 0.2 μm and equal to or less than 0.4 μm.

The n-type region 21 is provided between the p-well region 16 and the first face P1. The n-type region 21 is in contact with, for example, the first face P1. The n-type region 21 is in contact with, for example, the gate insulating layer 28. The n-type region 21 is provided between the oxygen region 22 and the first face P1.

The n-type region 21 is an n-type or n⁻-type SiC. The n-type region 21 contains, for example, nitrogen (N) or phosphorus (P) as an n-type impurity. The n-type impurity concentration in the n-type region 21 is lower than, for example, the n-type impurity concentration in the source region 18. The n-type impurity concentration in the n-type region 21 is, for example, equal to or more than 2×10¹⁷ cm⁻³ and equal to or less than 1×10¹⁸ cm⁻³.

When the n-type impurity contained in the n-type region 21 is nitrogen, the concentration of nitrogen atoms bonded to four silicon atoms contained in the n-type region 21 is higher than the concentration of nitrogen atoms bonded to three silicon atoms contained in the n-type region 21.

The depth of the n-type region 21 is smaller than the depth of the source region 18. The depth of the n-type region 21 is, for example, equal to or more than 0.02 μm and equal to or less than 0.2 μm.

The oxygen region 22 is disposed between the p-well region 16 and the first face P1. The oxygen region 22 is disposed between the p-well region 16 and the n-type region 21. The oxygen region 22 is a p-type SiC.

The oxygen region 22 is provided between the p-well region 16 and the gate electrode 30. The oxygen region 22 is provided between the p-well region 16 and the gate insulating layer 28.

The oxygen region 22 contains, for example, aluminum (Al) as a p-type impurity. The p-type impurity concentration in the oxygen region 22 is, for example, equal to or more than 1×10¹⁵ cm⁻³ and equal to or less than 1×10²⁰ cm⁻³. The maximum p-type impurity concentration in the oxygen region 22 is, for example, equal to or more than 1×10¹⁵ cm⁻³ and equal to or less than 1×10²⁰ cm⁻³.

The oxygen region 22 contains oxygen. The oxygen concentration in the oxygen region 22 is, for example, equal to or more than 1×10¹⁷ cm⁻³ and equal to or less than 1×10²³ cm⁻³. The maximum oxygen concentration in the oxygen region 22 is, for example, equal to or more than 1×10¹⁷ cm⁻³ and equal to or less than 1×10²³ cm⁻³.

The oxygen concentration in the oxygen region 22 is higher than, for example, the oxygen concentration in the p-well region 16. The oxygen concentration in the oxygen region 22 is higher than, for example, the maximum oxygen concentration in the p-well region 16.

The oxygen concentration in the oxygen region 22 is higher than, for example, the aluminum concentration in the oxygen region 22. The maximum oxygen concentration in the oxygen region 22 is, for example, higher than the maximum aluminum concentration in the oxygen region 22.

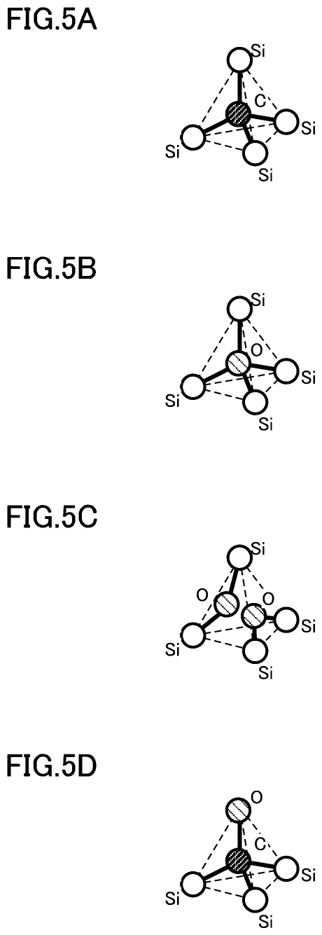

FIGS. 5A, 5B, 5C, and 5D are explanatory diagrams of an oxygen region in the first embodiment. FIG. 5A is a diagram showing the crystal structure of silicon carbide. FIG. 5B is a diagram showing a structure present in the oxygen region 22. FIG. 5C shows a structure containing an oxygen atom, which is different from FIG. 5B. FIG. 5D shows a structure containing an oxygen atom, which is different from FIGS. 5B and 5C.

In the structure shown in FIG. 5B, there is one oxygen atom bonded to four silicon atoms. In other words, in the structure shown in FIG. 5B, there is one oxygen atom disposed at the carbon site of the crystal structure of silicon carbide shown in FIG. 5A. In other words, in the structure shown in FIG. 5B, the carbon atom in the crystal structure of silicon carbide is substituted by one oxygen atom. The structure shown in FIG. 5B is referred to as a first structure.

In the structure shown in FIG. 5C, there are oxygen atoms bonded to two silicon atoms. In other words, in the structure shown in FIG. 5C, there are two oxygen atoms disposed at the carbon sites of the crystal structure of silicon carbide shown in FIG. 5A. In other words, in the structure shown in FIG. 5C, the carbon atom in the crystal structure of silicon carbide is substituted by two oxygen atoms. The structure shown in FIG. 5C is referred to as a second structure.

In the structure shown in FIG. 5D, there is an oxygen atom bonded to a carbon atom. In other words, in the structure shown in FIG. 5D, there is one oxygen atom disposed at the silicon site of the crystal structure of silicon carbide shown in FIG. 5A. In other words, in the structure shown in FIG. 5D, a silicon atom in the crystal structure of silicon carbide is substituted by one oxygen atom. The structure shown in FIG. 5D is referred to as a third structure.

The concentration of oxygen atoms bonded to four silicon atoms in the oxygen region 22 is higher than, for example, the concentration of oxygen atoms bonded to two silicon atoms in the oxygen region 22. In other words, the concentration of the first structure in the oxygen region 22 is higher than, for example, the concentration of the second structure in the oxygen region 22.

The concentration of oxygen atoms bonded to four silicon atoms in the oxygen region 22 is higher than, for example, the concentration of oxygen atoms bonded to the carbon atom in the oxygen region 22. In other words, the concentration of the first structure in the oxygen region 22 is higher than, for example, the concentration of the third structure in the oxygen region 22.

In addition, when the gate insulating layer 28 contains silicon oxide, the oxygen atom in the silicon oxide is bonded to two silicon atoms.

The gate insulating layer 28 is provided between the silicon carbide layer 10 and the gate electrode 30. The gate insulating layer 28 is provided between the drift region 14 and the gate electrode 30 and between the n-type region 21 and the gate electrode 30. The gate insulating layer 28 is provided above the drift region 14 and the n-type region 21. The gate insulating layer 28 is continuously formed on the surfaces of the drift region 14 and the n-type region 21.

The gate insulating layer 28 contains silicon oxide. The gate insulating layer 28 is an example of a silicon oxide layer.

The thickness of the gate insulating layer 28 is, for example, equal to or more than 30 nm and equal to or less than 100 nm. The gate insulating layer 28 functions as a gate insulating layer of the MOSFET 100.

The interface termination region 40 is disposed between the silicon carbide layer 10 and the gate insulating layer 28. The interface termination region 40 is disposed between the drift region 14 and the gate insulating layer 28 and between the n-type region 21 and the gate insulating layer 28. The interface termination region 40 contains nitrogen (N) as a termination element for terminating the dangling bond of the silicon carbide layer 10. The interface termination region 40 is an example of a region.

The concentration of nitrogen in the interface termination region 40 is equal to or more than 1×10²¹ cm⁻³. The concentration of nitrogen in the interface termination region 40 is, for example, equal to or more than 1×10²² cm⁻³.

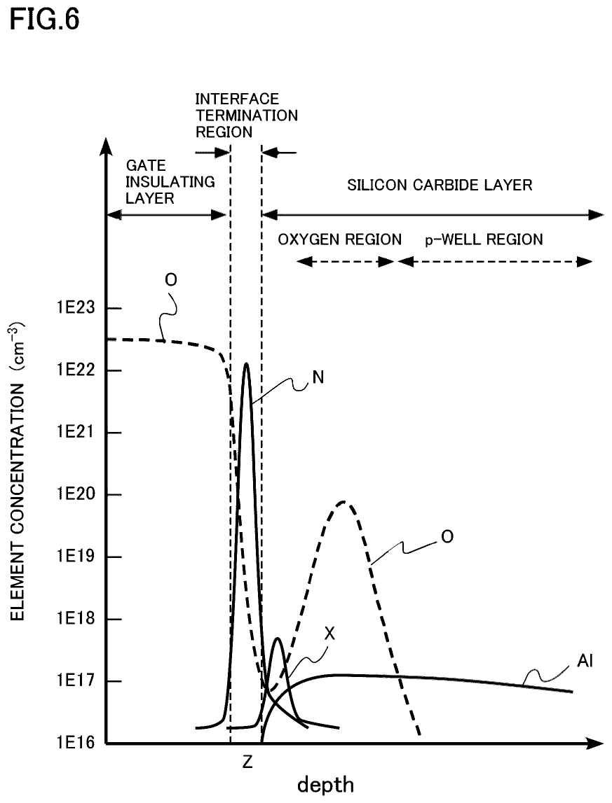

FIG. 6 is a diagram showing the element concentration distribution of the semiconductor device of the first embodiment. FIG. 6 is a diagram showing the element concentration distribution in the gate insulating layer 28, the interface termination region 40, and the silicon carbide layer 10. FIG. 6 shows the concentration distribution of nitrogen, oxygen, aluminum, and element X. The element X is an n-type impurity element contained in the n-type region 21. The element X is nitrogen (N) or phosphorus (P).

The nitrogen concentration distribution has a peak in the interface termination region 40. The peak nitrogen concentration is, for example, equal to or more than 1×10²¹ cm⁻³ and equal to or less than 4×10²³ cm⁻³.

The full width at half maximum with respect to the peak of the nitrogen concentration distribution is, for example, equal to or less than 1 nm. Nitrogen is segregated at the interface between the silicon carbide layer 10 and the gate insulating layer 28.

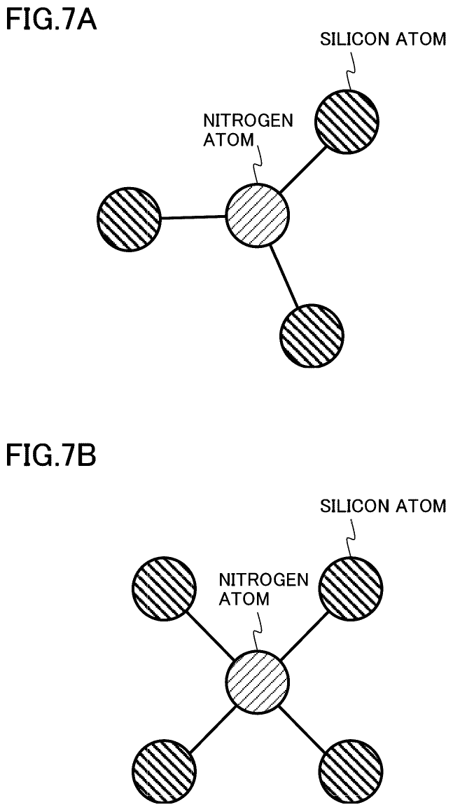

FIGS. 7A and 7B are schematic diagrams showing the bonding state of nitrogen atoms in the semiconductor device of the first embodiment. FIG. 7A shows a case of three-coordinated nitrogen atom, and FIG. 7B shows a case of four-coordinated nitrogen atom.

In the case of the three-coordinated nitrogen atom shown in FIG. 7A, the nitrogen atom is bonded to three silicon atoms. In the case of the four-coordinated nitrogen atom shown in FIG. 7B, the nitrogen atom is bonded to four silicon atoms.

In the interface termination region 40, the concentration of nitrogen atoms bonded to three silicon atoms is higher than the concentration of nitrogen atoms bonded to four silicon atoms. In other words, in the interface termination region 40, the concentration of three-coordinated nitrogen atoms is higher than the concentration of four-coordinated nitrogen atoms.

For example, 90% or more of the nitrogen atoms present in the interface termination region 40 are three-coordinated nitrogen atoms. The concentration of three-coordinated nitrogen atoms is, for example, equal to or more than 1×10²¹ cm⁻³.

The three-coordinated nitrogen atoms present in the interface termination region 40 terminate the dangling bonds on the surface of the silicon carbide layer 10.

The nitrogen atom in the interface termination region 40 substitutes the carbon atom in the uppermost layer of the silicon carbide layer 10. The nitrogen atom in the interface termination region 40 is tri-coordinated with the silicon carbide layer 10. The nitrogen atom is present at the position of the carbon atom in the crystal structure of silicon carbide. The silicon atoms of the silicon carbide layer 10 are tri-coordinated with the nitrogen atom in the interface termination region 40.

The nitrogen atom in the interface termination region 40 substitutes the carbon atom of the bilayer forming the uppermost layer of the silicon carbide layer 10. The nitrogen atom is finally tri-coordinated with the silicon carbide layer 10. Excess silicon atoms or carbon atoms are released from the silicon carbide layer 10 to the gate insulating layer 28 side. The nitrogen atom is present at the position of the carbon atom in the crystal structure of silicon carbide. Some of the silicon atoms on the outermost surface enter the gate insulating layer 28, and the nitrogen atom is tri-coordinated with the silicon atoms of the silicon carbide layer 10.

The nitrogen atom present in the bulk of the silicon carbide layer 10 and substituting the carbon site of the crystal structure of silicon carbide is a four-coordinated nitrogen atom. The four-coordinated nitrogen atom functions as an n-type dopant.

When the element X that is an n-type impurity element in the n-type region 21 is nitrogen (N), the n-type region 21 contains a four-coordinated nitrogen atom. In the n-type region 21, the concentration of nitrogen atoms bonded to four silicon atoms is higher than the concentration of nitrogen atoms bonded to three silicon atoms. In other words, in the n-type region 21, the concentration of four-coordinated nitrogen atoms is higher than the concentration of three-coordinated nitrogen atoms.

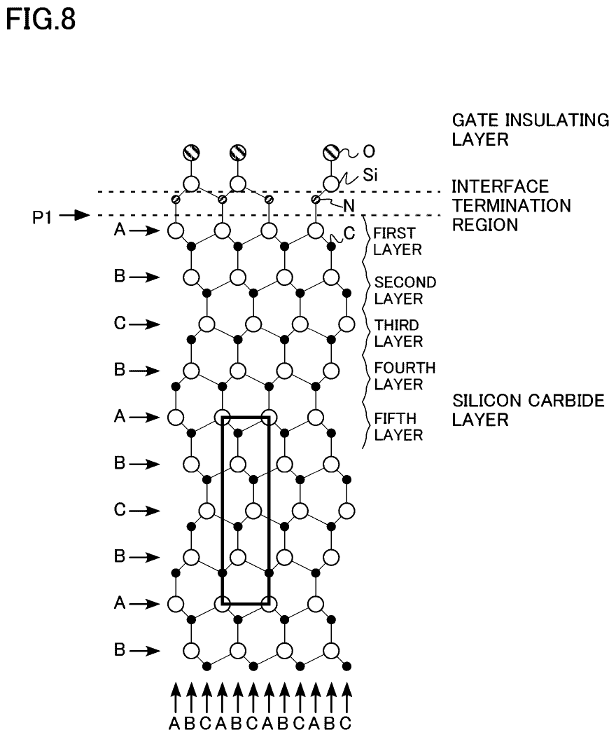

FIG. 8 is an explanatory diagram of the surface structure of the silicon carbide layer of the semiconductor device of the first embodiment. FIG. 8 shows the arrangement of atoms in the silicon carbide layer 10, the interface termination region 40, and the gate insulating layer 28.

The first face P1 of the silicon carbide layer 10 has a first surface structure. A first silicon atom is present in the first layer, which is an uppermost layer of the silicon carbide layer 10.

The first silicon atom is bonded to the nitrogen atom in the interface termination region 40. The nitrogen atom in the interface termination region 40 is bonded to the silicon atom in the gate insulating layer 28. The silicon atom in the gate insulating layer 28 is bonded to the oxygen atom in the gate insulating layer 28.

The percentage of the first silicon atom among a plurality of silicon atoms present in the first layer, which is an uppermost layer of the silicon carbide layer 10, is equal to or more than 90%. The first face P1 of the silicon carbide layer 10 has the first surface structure as a main surface structure.

Among the plurality of silicon atoms present in the first layer that is an uppermost layer of the silicon carbide layer 10, silicon atoms other than the first silicon atom may include, for example, the second silicon atom or the third silicon atom. The first face P1 of the silicon carbide layer 10 may include, for example, the second surface structure or the third surface structure.

The gate electrode 30 is provided on the gate insulating layer 28. The gate insulating layer 28 is interposed between the gate electrode 30 and the silicon carbide layer 10. The gate insulating layer 28 is interposed between the gate electrode 30 and the drift region 14. The gate insulating layer 28 is interposed between the gate electrode 30 and the n-type region 21.

The gate electrode 30 is, for example, polycrystalline silicon containing n-type impurities or p-type impurities.

The interlayer insulating film 32 is formed on the gate electrode 30. The interlayer insulating film 32 is disposed between the gate electrode 30 and the source electrode 34. The interlayer insulating film 32 is, for example, a silicon oxide film.

The source electrode 34 is electrically connected to the source region 18 and the p-well contact region 20. The source electrode 34 also functions as a p-well electrode for applying an electric potential to the p-well region 16. The source electrode 34 is in contact with, for example, the source region 18 and the p-well contact region 20.

The source electrode 34 has, for example, a stacked structure of a barrier metal layer of nickel (Ni) and a metal layer of aluminum on the barrier metal layer. The barrier metal layer formed of nickel and the silicon carbide layer may react with each other to form nickel silicide (NiSi, Ni₂Si, and the like). The barrier metal layer formed of nickel and the metal layer formed of aluminum may form an alloy by reaction.

The drain electrode 36 is provided on a side of the silicon carbide layer 10 opposite to the source electrode 34, that is, on the back surface side of the silicon carbide layer 10. The drain electrode 36 is electrically connected to the drain region 12. The drain electrode 36 is in contact with, for example, the drain region 12.

The drain electrode 36 is, for example, nickel. Nickel may react with the drain region 12 to form nickel silicide (NiSi, Ni₂Si, and the like).

In addition, in the first embodiment, the n-type impurity is, for example, nitrogen or phosphorus. Arsenic (As) or antimony (Sb) can also be applied as an n-type impurity.

In addition, in the first embodiment, the p-type impurity is, for example, aluminum. Boron (B), gallium (Ga), and indium (In) can also be applied as p-type impurities.

Next, an example of a method for manufacturing the semiconductor device of the first embodiment will be described.

A method for manufacturing the semiconductor device of the first embodiment: ion-implanting aluminum (Al) into a predetermined region of a silicon carbide layer with a surface having an off-angle of 0° or more and 8° or less with respect to a {0001} face; ion-implanting at least one element of nitrogen (N) or phosphorus (P) into the predetermined region; ion-implanting silicon (Si) into the predetermined region; ion-implanting oxygen (O) into the predetermined region; ion-implanting carbon (C) into the predetermined region; forming a carbon film on the silicon carbide layer; performing a first heat treatment at 1600° C. or higher; removing the carbon film; performing a second heat treatment at 1100° C. or higher in an atmosphere containing argon or hydrogen; forming a silicon oxide film on the silicon carbide layer; performing a third heat treatment in an atmosphere containing nitrogen; and forming a gate electrode on the silicon oxide film.

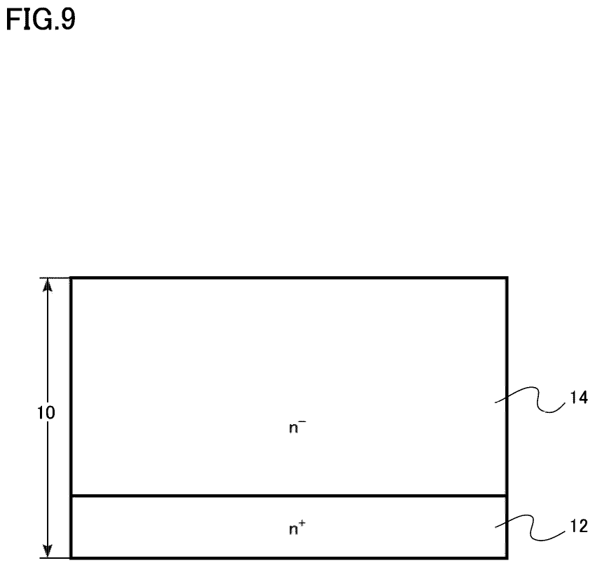

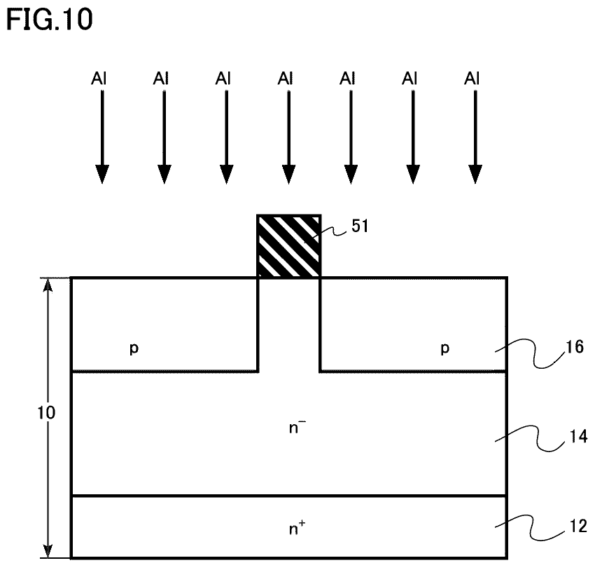

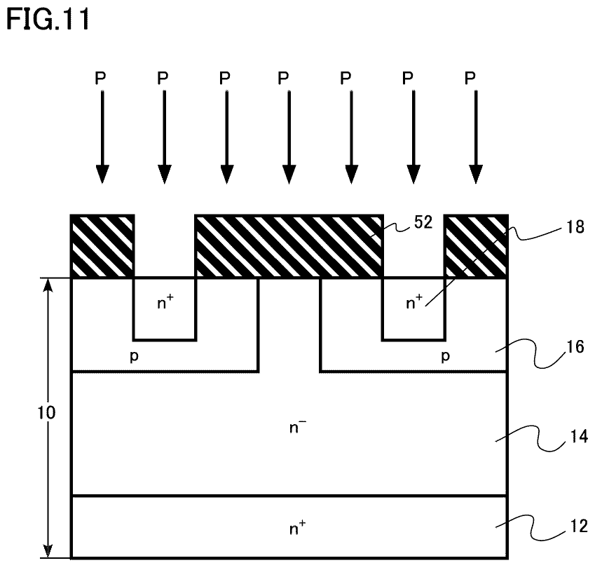

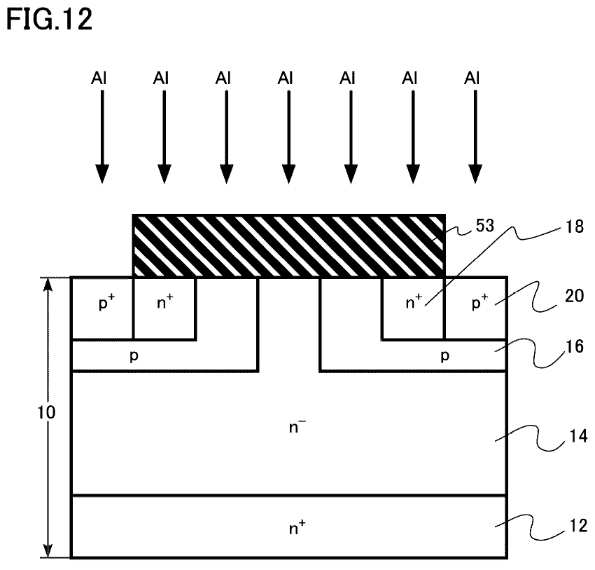

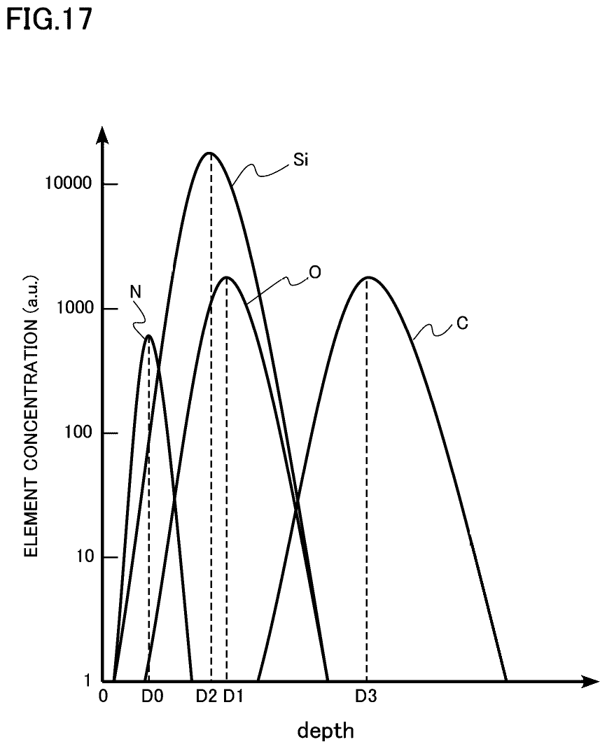

FIGS. 9 to 22 are explanatory diagrams of the method for manufacturing the semiconductor device of the first embodiment. FIGS. 9 to 16 and FIGS. 18 to 22 are cross-sectional views during the manufacturing process. FIG. 17 is a diagram showing the element distribution immediately after ion implantation. In addition, a case where the element X, which is an impurity element in the n-type region 21, is nitrogen will be described as an example.

First, the silicon carbide layer 10 is prepared (FIG. 9). The surface of the silicon carbide layer 10 has an off-angle of 0° or more and 8° or less with respect to the {0001} face. The silicon carbide layer 10 includes an n⁺-type drain region 12 and an n⁻-type drift region 14. The drift region 14 is formed, for example, on the drain region 12 by an epitaxial growth method.

The drain region 12 contains nitrogen as an n-type impurity. The n-type impurity concentration in the drain region 12 is, for example, equal to or more than 1×10¹⁸ cm⁻³ and equal to or less than 1×10²¹ cm⁻³.

The drift region 14 contains nitrogen as an n-type impurity. The n-type impurity concentration in the drift region 14 is, for example, equal to or more than 1×10¹⁵ cm⁻³ and equal to or less than 2×10¹⁶ cm⁻³. The thickness of the drift region 14 is, for example, equal to or more than 5 μm and equal to or less than 100 μm.

Then, a first mask material 51 is formed, for example, by forming an insulating film and patterning the insulating film by photolithography and etching. Then, by using the first mask material 51 as an ion implantation mask, aluminum is ion-implanted into the drift region 14. The p-well region 16 is formed by ion implantation (FIG. 10).

Then, a second mask material 52 is formed, for example, by forming an insulating film and patterning the insulating film by photolithography and etching. Then, by using the second mask material 52 as an ion implantation mask, phosphorus is ion-implanted into the p-well region 16 to form the source region 18 (FIG. 11). Thereafter, the second mask material 52 is removed.

Then, a third mask material 53 is formed, for example, by forming an insulating film and patterning the insulating film by photolithography and etching. By using the third mask material 53 as an ion implantation mask, aluminum is ion-implanted into the p-well region 16 to form the p-well contact region 20 (FIG. 12). Thereafter, the third mask material 53 is removed.

Then, a fourth mask material 54 is formed, for example, by forming an insulating film and patterning the insulating film by photolithography and etching. The fourth mask material 54 is formed so that the p-well region 16 is exposed. The exposed p-well region 16 is an example of a predetermined region.

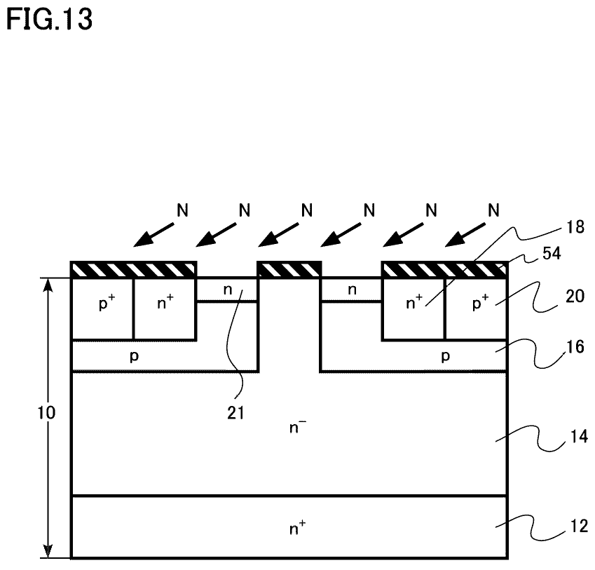

Then, by using the fourth mask material 54 as an ion implantation mask, nitrogen is ion-implanted into the p-well region 16 to form the n-type region 21 (FIG. 13). For nitrogen ion implantation, for example, an oblique ion implantation method is used. By using the oblique ion implantation method, nitrogen can be introduced into the shallow position of the silicon carbide layer 10. The inclination angle between the nitrogen ion implantation direction and the normal of the surface of the silicon carbide layer 10 is, for example, equal to or more than 45°.

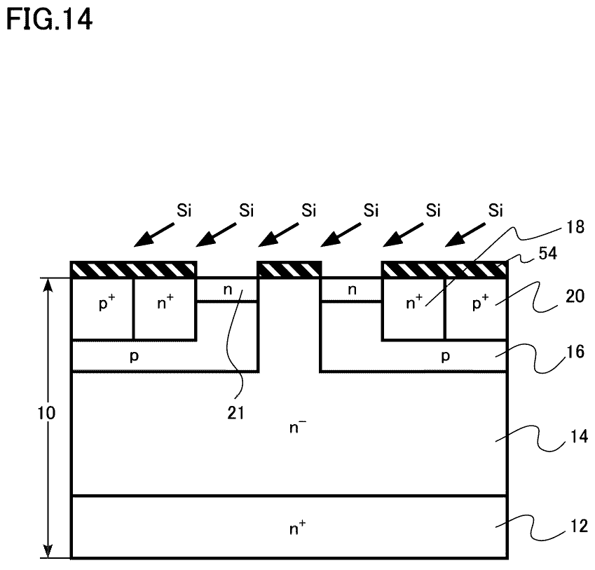

Then, silicon is ion-implanted into the p-well region 16 by using the fourth mask material 54 as an ion implantation mask (FIG. 14).

For silicon ion implantation, for example, an oblique ion implantation method is used. By using the oblique ion implantation method, silicon can be introduced into the shallow position of the silicon carbide layer 10. The inclination angle between the silicon ion implantation direction and the normal of the surface of the silicon carbide layer 10 is, for example, equal to or more than 45°.

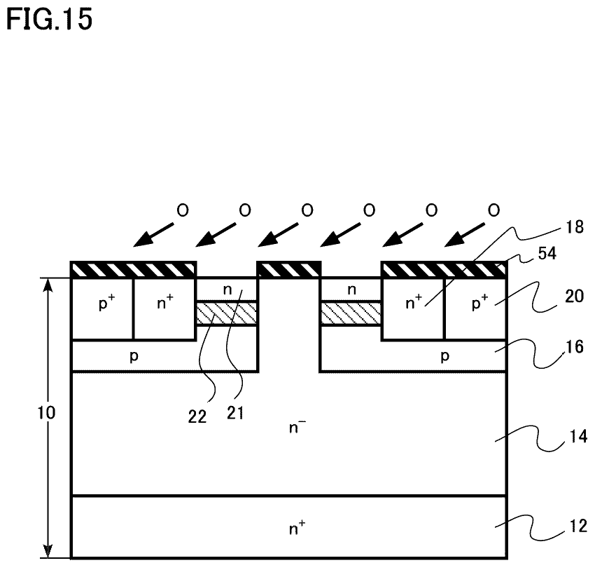

Then, by using the fourth mask material 54 as an ion implantation mask, oxygen is ion-implanted into the silicon carbide layer 10 to form the oxygen region 22 (FIG. 15). The oxygen region 22 is formed in the p-well region 16.

Oxygen ion implantation breaks the carbon bonds in the silicon carbide layer 10, so that the carbon vacancy in the silicon carbide layer 10 increases.

For oxygen ion implantation, for example, an oblique ion implantation method is used. By using the oblique ion implantation method, oxygen can be introduced into the shallow position of the silicon carbide layer 10. The inclination angle between the oxygen ion implantation direction and the normal of the surface of the silicon carbide layer 10 is, for example, equal to or more than 45°. Oxygen ion implantation is performed, for example, from the same direction as silicon ion implantation.

The crystal structure in the vicinity of the surface of the silicon carbide layer 10 is disturbed by the ion implantation of silicon. By the silicon ion implantation, for example, the vicinity of the surface of the silicon carbide layer 10 is amorphized.

By performing the silicon ion implantation before the oxygen ion implantation, channeling during the oxygen ion implantation is suppressed. Therefore, it is possible to prevent the oxygen region 22 from becoming deep. It is also possible to perform the silicon ion implantation after the oxygen ion implantation.

In the oblique ion implantation method, the ion implantation region can be limited to the vicinity of the surface. In addition, since channeling is suppressed, the implanted ions can be immediately stopped in the vicinity of the surface. Therefore, according to the oblique ion implantation method, it is possible to limit the ion distribution at the time of implantation to an extremely shallow region in the vicinity of the surface.

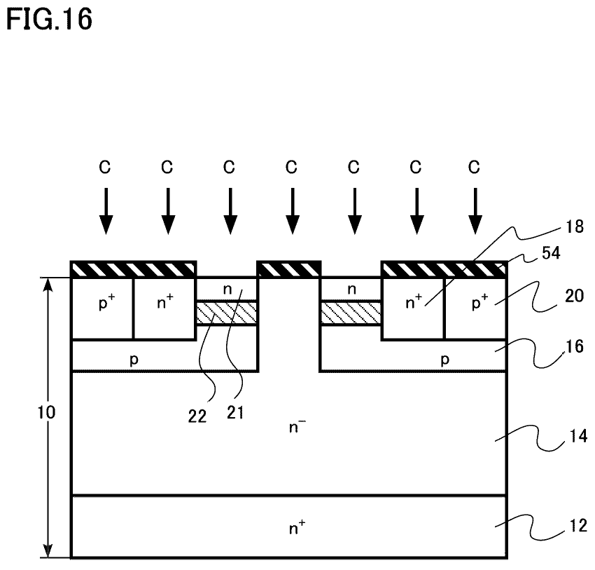

Then, carbon is ion-implanted into the silicon carbide layer 10 by using the fourth mask material 54 as an ion implantation mask (FIG. 16).

FIG. 17 shows the profile of ion implantation of nitrogen (N), oxygen (O), silicon (Si), and carbon (C). The horizontal axis indicates the depth from the surface of the silicon carbide layer 10, and the vertical axis indicates the element concentration.

In FIG. 17, after ion implantation, the depth at which the nitrogen concentration is maximized is assumed to be a 0th depth DO, the depth at which the oxygen concentration is maximized is assumed to be a first depth D1, the depth at which the silicon concentration is maximized is assumed to be a second depth D2, and the depth at which the carbon concentration is maximized is assumed to be a third depth D3.

The 0th depth is smaller than the first depth D1, the second depth D2, and the third depth D3. The first depth D1 and the second depth D2 are smaller than the third depth D3.

For example, the silicon ion implantation profile covers the entire oxygen ion implantation profile. Since silicon is present in the vicinity, it becomes easy for the oxygen to enter the carbon site of the crystal structure of silicon carbide.

For example, the carbon ion implantation profile is positioned well behind the oxygen ion implantation profile. The presence of carbon fills the carbon vacancies, which makes it difficult for oxygen to diffuse. Therefore, the diffusion of oxygen in the depth direction of the silicon carbide layer 10 is suppressed.

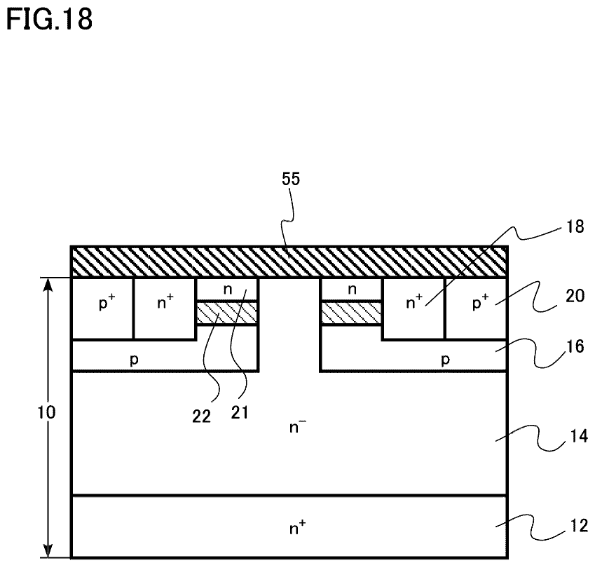

Then, a carbon film 55 is formed on the silicon carbide layer 10 (FIG. 18).

Then, a first heat treatment is performed. The first heat treatment is performed at 1600° C. or higher. The first heat treatment is performed in a non-oxidizing atmosphere. The first heat treatment is performed, for example, in an inert gas atmosphere. The first heat treatment is performed, for example, in an argon gas atmosphere.

By the first heat treatment, aluminum, phosphorus, and nitrogen ion-implanted into the silicon carbide layer 10 are activated. The first heat treatment is the activation annealing of aluminum, phosphorus, and nitrogen.

In addition, by the first heat treatment, oxygen atoms fill a large number of carbon vacancies formed in the vicinity of the surface of the silicon carbide layer 10. In other words, an oxygen atom bonded to four silicon atoms is formed. In other words, a large number of first structures are formed in which the carbon atom in the crystal structure of silicon carbide is substituted by one oxygen atom.

During the heat treatment, oxygen is present as atoms in the oxygen region 22. Therefore, the formation of the first structure in which the carbon atom in the crystal structure of silicon carbide is substituted by one oxygen atom is promoted rather than the formation of the second structure in which the carbon atom is substituted by two oxygen atoms.

During the heat treatment, silicon atoms are present in the oxygen region 22. Therefore, the formation of the first structure in which the carbon atom in the crystal structure of silicon carbide is substituted by one oxygen atom is promoted rather than the formation of the third structure in which the silicon atom in the crystal structure of silicon carbide is substituted by one oxygen atom.

In addition, during the heat treatment, the carbon concentration is higher than the oxygen concentration in a region deeper than the oxygen region 22. Therefore, since the carbon atom enters the carbon vacancy in the region deeper than the oxygen region 22 in preference to the oxygen atom, the first structure is difficult to be formed.

The carbon film 55 suppresses the desorption of silicon or carbon from the silicon carbide layer 10 into the atmosphere during the first heat treatment. In addition, the carbon film 55 absorbs excess interstitial carbon in the silicon carbide layer 10 during the first heat treatment.

The first heat treatment includes, for example, a first step whose temperature is 1600° C. or higher and a second step whose temperature is lower than the temperature of the first step. The temperature of the second step is, for example, equal to or lower than 1000° C.

For example, in the first step, aluminum, nitrogen, and phosphorus ion-implanted into the silicon carbide layer 10 are activated, so that the interstitial carbon fills the carbon vacancies. For example, in the second step of low temperature, excess interstitial carbon is expelled from the silicon carbide layer 10 and absorbed by the carbon film 55.

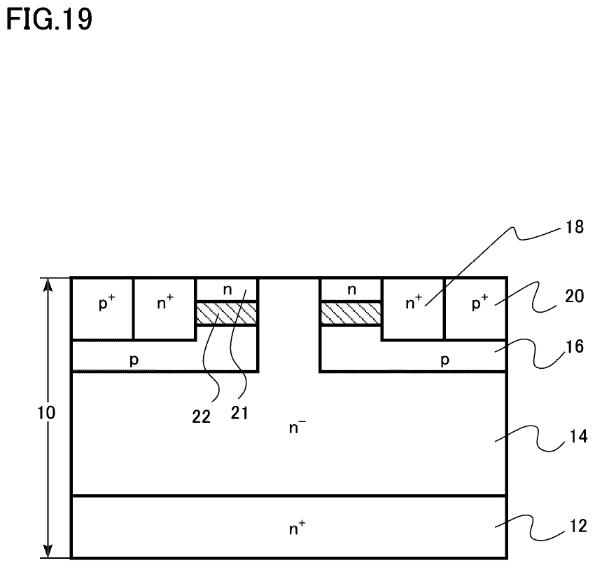

Then, the carbon film 55 is removed (FIG. 19).

Then, a second heat treatment is performed. The second heat treatment is performed at 1100° C. or more. The second heat treatment is performed in an atmosphere containing argon or hydrogen. The second heat treatment is performed in an argon gas atmosphere or a hydrogen gas atmosphere. Due to the second heat treatment, atom migration occurs on the surface of the silicon carbide layer 10.

By the second heat treatment, a third surface structure is formed on the surface of the silicon carbide layer 10. The surface of the silicon carbide layer 10 has the third surface structure as a main surface structure. The silicon atom disposed in the first layer of the outermost surface of the third surface structure is the third silicon atom. The site position occupied by the third silicon atom is different from the site position occupied by a silicon atom in the third layer, and is also different from the site position occupied by a silicon atom in the fifth layer.

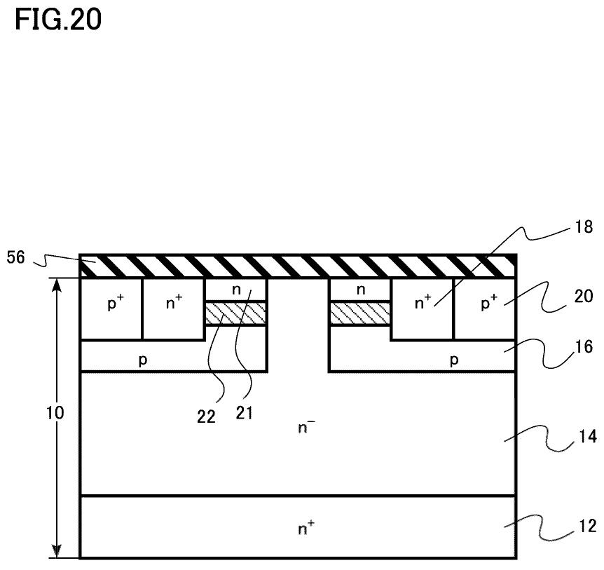

Then, a silicon oxide film 56 is formed on the silicon carbide layer 10 (FIG. 20). The silicon oxide film 56 finally becomes the gate insulating layer 28.

The silicon oxide film 56 is formed by, for example, a vapor deposition method. The silicon oxide film 56 is formed by, for example, a chemical vapor deposition method (CVD method) or a physical vapor deposition method (PVD method). The formation temperature of the silicon oxide film 56 is, for example, equal to or lower than 800° C.

The silicon oxide film 56 is a sedimentary film. The thickness of the silicon oxide film 56 is, for example, equal to or more than 30 nm and equal to or less than 100 nm.

The silicon oxide film 56 is, for example, a silicon oxide film formed by a CVD method using tetraethyl orthosilicate (TEOS) as a source gas. In addition, the silicon oxide film 56 is, for example, a silicon oxide film formed by a CVD method using dichlorosilane gas (SiH₂Cl₂) and nitrous oxide gas (N₂O) as source gases.

Then, a third heat treatment is performed. The third heat treatment is performed in an atmosphere containing ammonia gas (NH₃).

For example, the ammonia gas (NH₃) is supplied to a reaction furnace containing the silicon carbide layer 10 to perform heat treatment.

The temperature of the third heat treatment is, for example, equal to or higher than 1200° C. and equal to or lower than 1600° C. The partial pressure of the ammonia gas in the atmosphere of the third heat treatment is, for example, equal to or more than 90%.

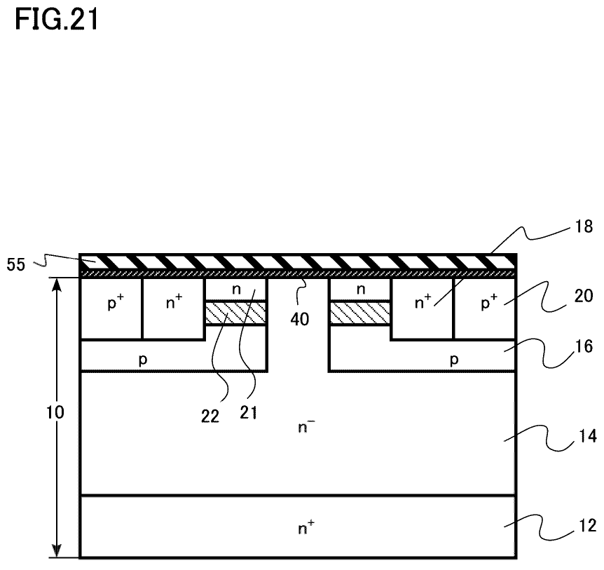

By the third heat treatment, the interface termination region 40 is formed at the interface between the silicon carbide layer 10 and the silicon oxide film (FIG. 21). By the third heat treatment, the surface of the silicon carbide layer 10 is converted into the first surface structure.

The third heat treatment also functions as densify annealing of the silicon oxide film. By the third heat treatment, the silicon oxide film 56 becomes a high-density film.

Then, a fourth heat treatment is performed. The fourth heat treatment is performed in an atmosphere containing nitrogen oxide gas (NOX). The nitrogen oxide gas is, for example, a nitric oxide gas (NO). In addition, the nitrogen oxide gas is, for example, a nitrous oxide gas (N₂O).

For example, the nitrogen oxide gas (NOx) is supplied to a reaction furnace containing the silicon carbide layer 10 to perform heat treatment.

The temperature of the fourth heat treatment is, for example, equal to or higher than 750° C. and equal to or lower than 1050° C. The temperature of the fourth heat treatment is, for example, lower than the temperature of the third heat treatment.

The partial pressure of the nitrogen oxide gas in the atmosphere of the fourth heat treatment is, for example, equal to or more than 10%.

By the fourth heat treatment, nitrogen in the silicon oxide film is removed. By the fourth heat treatment, a silicon oxide film with reduced nitrogen defects is formed.

Then, the gate electrode 30 is formed on the gate insulating layer 28. The gate electrode 30 is, for example, polycrystalline silicon containing n-type impurities or p-type impurities.

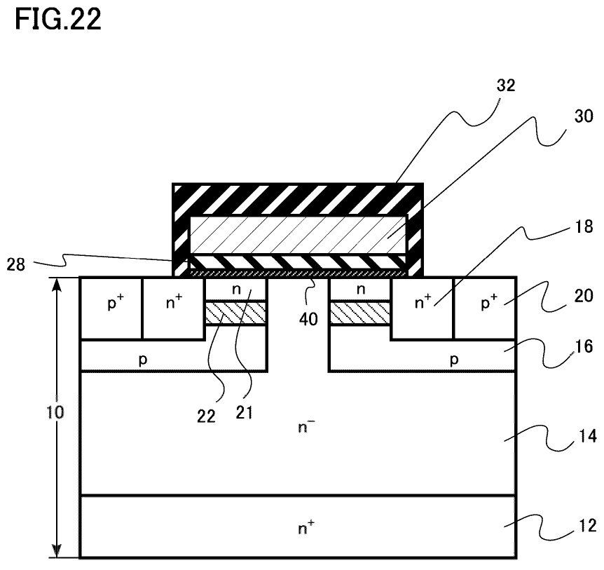

Then, the interlayer insulating film 32 is formed on the gate electrode 30 (FIG. 22). The interlayer insulating film 32 is, for example, a silicon oxide film.

Then, the source electrode 34 and the drain electrode 36 are formed. The source electrode 34 is formed on the source region 18 and the p-well contact region 20. The source electrode 34 is formed, for example, by sputtering nickel (Ni) and aluminum (Al). The drain electrode 36 is formed on the back surface side of the silicon carbide layer 10. The drain electrode 36 is formed, for example, by sputtering nickel.

By the manufacturing method described above, the MOSFET 100 shown in FIG. 1 is formed.

Next, the function and effect of the semiconductor device of the first embodiment and the method for manufacturing the semiconductor device will be described.

In the MOSFET 100 of the first embodiment, the main surface structure of the surface of the silicon carbide layer 10 is the first surface structure having a small interface state between the silicon carbide layer 10 and the gate insulating layer 28. Therefore, the decrease in reliability of the gate insulating layer due to the interface state or the decrease in mobility of carriers due to the interface state is suppressed. In addition, the interface termination region 40 is provided in which nitrogen is segregated between the silicon carbide layer 10 and the gate insulating layer 28. Therefore, since the dangling bond on the surface of the silicon carbide layer 10 is reduced, the decrease in mobility of carriers is suppressed. As a result, the characteristics of the MOSFET 100 are improved.

In addition, in the MOSFET 100 of the first embodiment, it is possible to suppress a decrease in the threshold voltage by providing the oxygen region 22. In addition, in the MOSFET 100 of the first embodiment, high mobility is realized by providing the oxygen region 22.

In addition, in the method for manufacturing the MOSFET 100 of the first embodiment, in order for the first surface structure having a small interface state to be the main surface structure, the third surface structure is formed on the surface of the silicon carbide layer 10 during the manufacturing process. Then, by converting the third surface structure into the first surface structure, the first surface structure finally becomes the main surface structure.

Hereinafter, the function and effect of the semiconductor device of the first embodiment and the method for manufacturing the semiconductor device will be described in detail.

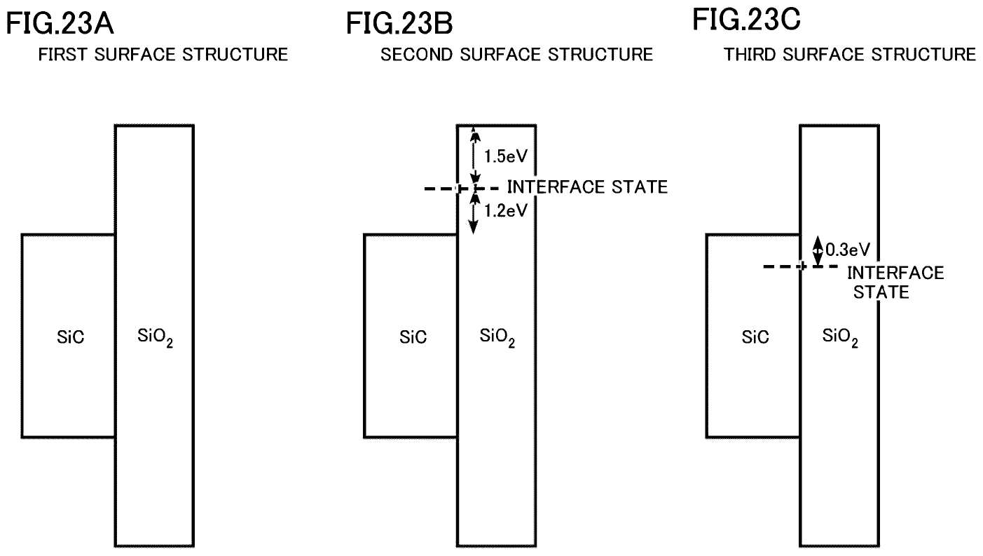

FIGS. 23A, 23B, and 23C are explanatory diagrams of the function and effect of the semiconductor device of the first embodiment. FIGS. 23A, 23B, and 23C are diagrams showing the result of calculating the energy state of each surface structure of the silicon carbide layer shown in FIGS. 4A, 4B, and 4C by first-principle calculation. FIG. 23A shows the case of the first surface structure shown in FIG. 4A, FIG. 23B shows the case of the second surface structure shown in FIG. 4B, and FIG. 23C shows the case of the third surface structure shown in FIG. 4C.

FIGS. 23A, 23B, and 23C show band diagrams of each surface structure. FIGS. 23A, 23B, and 23C show calculation results for a state in which the silicon carbide layer (Sic) and the silicon oxide layer (SiO₂) are ideally bonded to each other.

As shown in FIG. 23A, in the case of the first surface structure, no interface state is formed between the silicon carbide layer (Sic) and the silicon oxide layer (SiO₂).

On the other hand, as shown in FIG. 23B, in the case of the second surface structure, the interface state is formed at a position 1.2 eV higher than the lower end of the conduction band of the silicon carbide layer (Sic). In the case of the MOS structure, a leakage current of the gate insulating layer through the interface state may be generated to decrease the reliability of the gate insulating layer.

In addition, as shown in FIG. 23C, in the case of the third surface structure, the interface state is formed at a position 0.3 eV lower than the lower end of the conduction band of the silicon carbide layer (Sic). In the case of the MOSFET, electrons may be trapped at the interface state to decrease the mobility of carriers.

From the above calculation results, it can be seen that the surface of the silicon carbide layer desirably has the first surface structure in which no interface state is formed in order to improve the characteristics of the MOSFET.

In the MOSFET 100 of the first embodiment, the percentage of the first silicon atom among a plurality of silicon atoms present in the first layer, which is an uppermost layer of the silicon carbide layer 10, is equal to or more than 90%. Therefore, 90% or more of the surface of the silicon carbide layer 10 has the first surface structure. As a result, the decrease in reliability of the gate insulating layer 28 due to the interface state or the decrease in mobility of carriers due to the interface state is suppressed, so that the characteristics of the MOSFET 100 are improved.

From the viewpoint of suppressing the decrease in reliability of the gate insulating layer 28 or the decrease in mobility of carriers, the percentage of the first silicon atom among a plurality of silicon atoms present in the first layer is preferably equal to or more than 95%, more preferably equal to or more than 98%.

Even if the surface of the silicon carbide layer 10 has the first surface structure, it is difficult in manufacturing to make the bonding state between the silicon carbide layer 10 and the gate insulating layer 28 ideal. On the surface of the silicon carbide layer 10, dangling bonds of silicon atoms or carbon atoms can occur. When a dangling bond is present on the surface of the silicon carbide layer 10, an interface state is formed at the interface between the silicon carbide layer 10 and the gate insulating layer 28, resulting in a decrease in mobility of carriers.

The MOSFET 100 of the first embodiment includes the interface termination region 40 where nitrogen is segregated between the silicon carbide layer 10 and the gate insulating layer 28. In the interface termination region 40, the nitrogen atom is tri-coordinated with the silicon atoms, so that the dangling bond is reduced. Therefore, a MOSFET in which a decrease in mobility of carriers is suppressed is realized.

The nitrogen concentration in the interface termination region 40 is equal to or more than 1×10²¹ cm⁻³. From the viewpoint of suppressing the decrease in mobility of carriers of the MOSFET 100, the nitrogen concentration in the interface termination region 40 is preferably equal to or more than 1×10²² cm⁻³, more preferably equal to or more than 5×10²² cm⁻³. From the viewpoint of suppressing the decrease in mobility of carriers of the MOSFET 100, the peak nitrogen concentration in the interface termination region 40 of the nitrogen concentration distribution is preferably equal to or more than 1×10²² cm⁻³, more preferably equal to or more than 5× 10²² cm⁻³.

Excess nitrogen in the interface termination region 40 may become a charge trap. Therefore, the peak nitrogen concentration in the interface termination region 40 of the nitrogen concentration distribution is preferably equal to or less than 4×10²³ cm⁻³, more preferably equal to or less than 1×10²³ cm⁻³.

The peak nitrogen concentration in the interface termination region 40 of the nitrogen concentration distribution is preferably 5.0×10²² cm⁻³±5%. When the peak nitrogen concentration is in the range of 5.0×10²² cm⁻³±5%, the MOSFET 100 exhibits good characteristics, especially with few charge traps.

The area density of nitrogen in the interface termination region 40 is preferably equal to or more than 1×10¹⁴ cm⁻² and equal to or less than 2.5×10¹⁵ cm⁻². The area density of nitrogen in the interface termination region 40 is preferably 1.4×10¹⁵ cm^{-2±5}%. When the area density of nitrogen is in the above range, the MOSFET 100 exhibits good characteristics, especially with few charge traps.

From the viewpoint of suppressing the decrease in mobility of carriers of the MOSFET 100, it is preferable that 90% or more of the nitrogen atoms present in the interface termination region 40 are three-coordinated nitrogen atoms. More preferably, 99% or more of the nitrogen atoms present in the interface termination region 40 are three-coordinated nitrogen atoms. The concentration of three-coordinated nitrogen atoms present in the interface termination region 40 is, for example, equal to or more than 1×10²¹ cm⁻³. The concentration of four-coordinated nitrogen atoms present in the interface termination region 40 is, for example, equal to or less than 1×10¹⁹ cm⁻³.

The interface termination region 40 is formed by supplying nitrogen to the interface between the silicon carbide layer 10 and the gate insulating layer 28 after forming the gate insulating layer 28. The interface termination region 40 is formed by substituting the carbon atom in the uppermost layer of the surface of the silicon carbide layer 10 with the nitrogen atom. At this time, the silicon atom in the uppermost layer is bonded to the oxygen atom in the gate insulating layer 28 to become a part of the gate insulating layer 28.

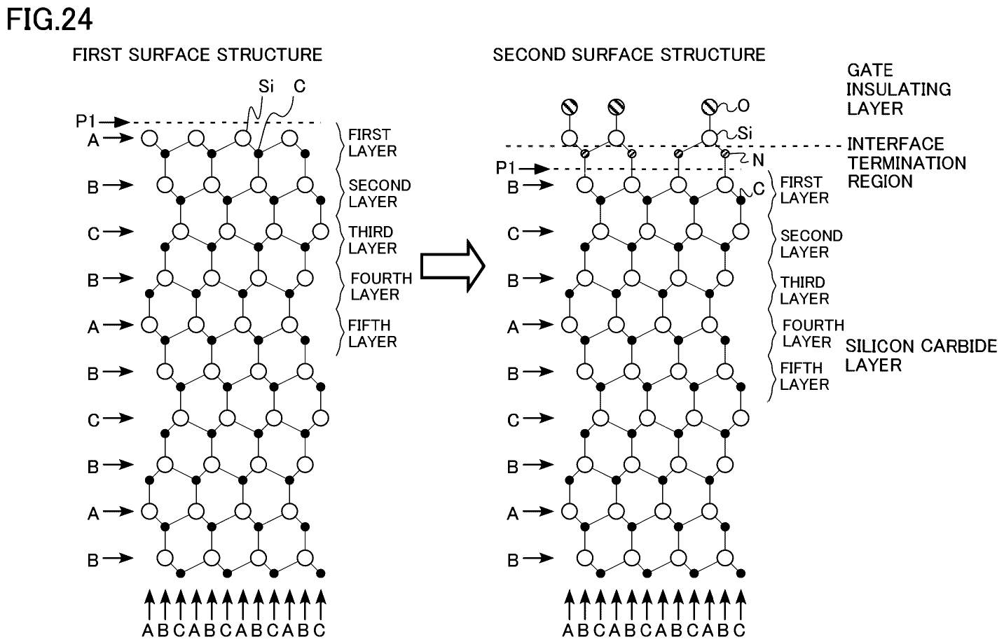

FIG. 24 is an explanatory diagram of the function and effect of the semiconductor device of the first embodiment. FIG. 24 is a diagram showing a change in a surface structure when a gate insulating layer and an interface termination region are formed on the surface of a silicon carbide layer having the first surface structure.

As shown in FIG. 24, when forming the interface termination region, the carbon atom in the first layer that is the uppermost layer is substituted by the nitrogen atom. The silicon atom in the first layer that is the uppermost layer is bonded to the oxygen atom in the gate insulating layer to become a part of the gate insulating layer. Before the interface termination region is formed, the silicon atom in the first layer is the first silicon atom as shown on the left side of FIG. 24. On the other hand, after the interface termination region is formed, the silicon atom in the first layer is the second silicon atom as shown on the right side of FIG. 24. In other words, after the interface termination region is formed, the surface of the silicon carbide layer is converted from the first surface structure to the second surface structure.

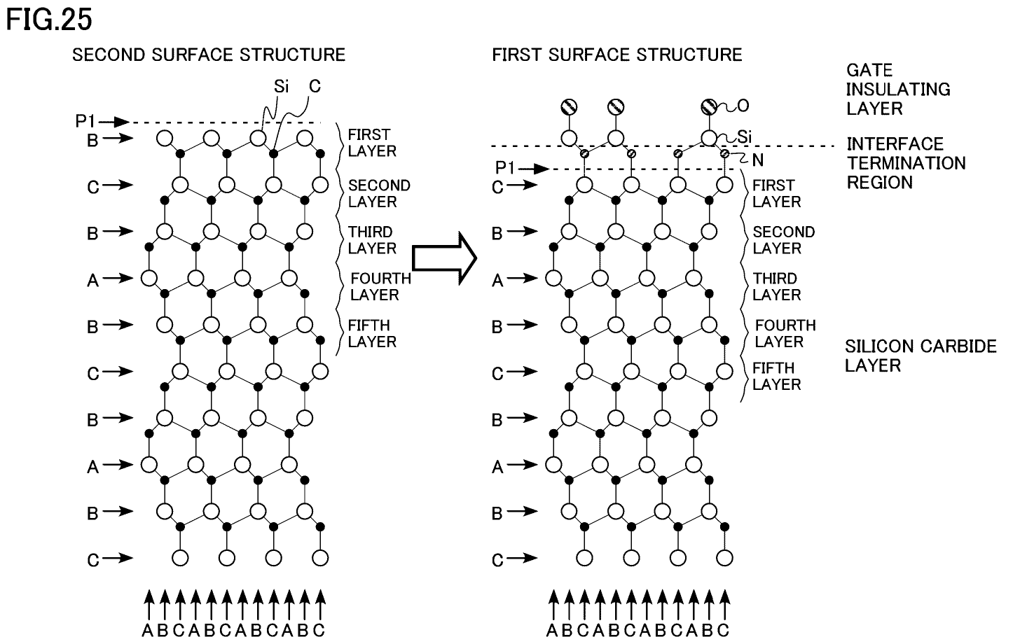

FIG. 25 is an explanatory diagram of the function and effect of the semiconductor device of the first embodiment. FIG. 25 is a diagram showing a change in a surface structure when a gate insulating layer and an interface termination region are formed on the surface of a silicon carbide layer having the second surface structure.

As shown in FIG. 25, when forming the interface termination region, the carbon atom in the first layer that is the uppermost layer is substituted by the nitrogen atom. The silicon atom in the first layer that is the uppermost layer is bonded to the oxygen atom in the gate insulating layer to become a part of the gate insulating layer. Before the interface termination region is formed, the silicon atom in the first layer is the second silicon atom as shown on the left side of FIG. 25. On the other hand, after the interface termination region is formed, the silicon atom in the first layer is the first silicon atom as shown on the right side of FIG. 25. In other words, after the interface termination region is formed, the surface of the silicon carbide layer is converted from the second surface structure to the first surface structure.

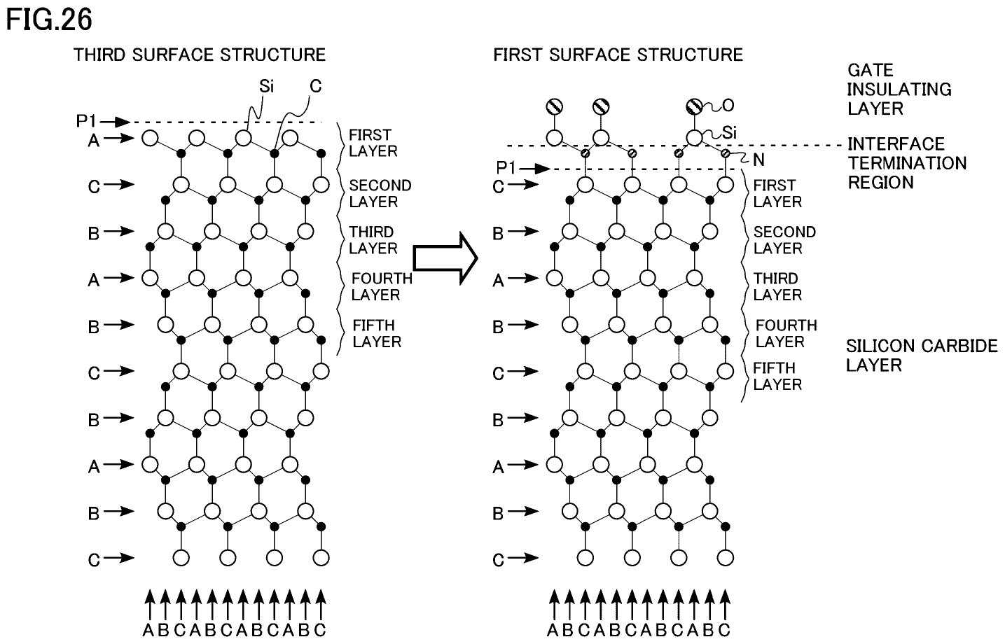

FIG. 26 is an explanatory diagram of the function and effect of the semiconductor device of the first embodiment. FIG. 26 is a diagram showing a change in a surface structure when a gate insulating layer and an interface termination region are formed on the surface of a silicon carbide layer having the third surface structure.

As shown in FIG. 26, when forming the interface termination region, the carbon atom in the first layer that is the uppermost layer is substituted by the nitrogen atom. The silicon atom in the first layer that is the uppermost layer is bonded to the oxygen atom in the gate insulating layer to become a part of the gate insulating layer. Before the interface termination region is formed, the silicon atom in the first layer is the third silicon atom as shown on the left side of FIG. 26. On the other hand, after the interface termination region is formed, the silicon atom in the first layer is the first silicon atom as shown on the right side of FIG. 26. In other words, after the interface termination region is formed, the surface of the silicon carbide layer is converted from the third surface structure to the first surface structure.

As described above, from the viewpoint of improving the characteristics of the MOSFET, it is preferable that the surface of the silicon carbide layer has a first surface structure, and it is not preferable that the surface of the silicon carbide layer has a second surface structure or a third surface structure.

As described with reference to FIGS. 24, 25, and 26, in order to make the surface of the silicon carbide layer have a first surface structure after forming the interface termination region, the surface of the silicon carbide layer needs to have a second surface structure or a third surface structure before forming the interface termination region.

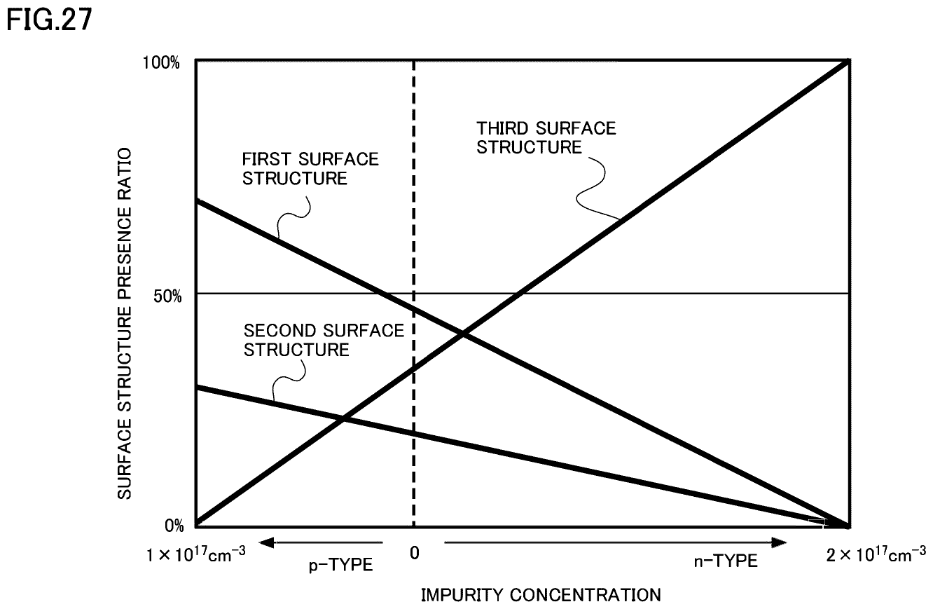

FIG. 27 is an explanatory diagram of the function and effect of the semiconductor device of the first embodiment. FIG. 27 is a diagram showing the impurity concentration dependence of the presence ratio of the surface structure of the silicon carbide layer. FIG. 27 shows a result of calculating the presence ratio of the surface structure that can be stably present on the surface of the silicon carbide layer by using the concentration of p-type impurities or n-type impurities contained in the silicon carbide layer as a parameter. The calculation is performed by the first-principle calculation.

As shown in FIG. 27, as the concentration of p-type impurities contained in the silicon carbide layer increases, the presence ratio of the first surface structure and the second surface structure increases. On the other hand, as the concentration of n-type impurities contained in the silicon carbide layer increases, the presence ratio of the third surface structure increases.

As described above, in order to make the surface of the silicon carbide layer have a first surface structure after forming the interface termination region, the surface of the silicon carbide layer needs to have a second surface structure or a third surface structure before forming the interface termination region.

If the silicon carbide layer contains n-type impurities before forming the interface termination region, the presence ratio of the third surface structure can be increased. In particular, when the concentration of n-type impurities contained in the silicon carbide layer is about 2×10¹⁷ cm⁻³, the presence ratio of the third surface structure can be 100%.

Conceivably, the reason why the presence ratio of the third surface structure is high when the silicon carbide layer contains n-type impurities is that electrons are supplied from the n-type impurities and accordingly, the third surface structure becomes stable.

In the method for manufacturing the MOSFET 100 of the first embodiment, the n-type region 21 is formed on the surface of the p-well region 16 before the interface termination region 40 is formed. By forming the n-type region 21 on the surface of the p-well region 16, the surface of the silicon carbide layer 10 can be made into a third surface structure before the interface termination region 40 is formed.

Due to the second heat treatment, atom migration occurs on the surface of the silicon carbide layer 10. Since the atom migration occurs in a state in which electrons can be supplied from the n-type region 21, the third surface structure is formed as a stable structure on the surface of the silicon carbide layer 10.

In addition, in the method for manufacturing the MOSFET 100 of the first embodiment, the gate insulating layer 28 is formed by the vapor deposition method. Therefore, oxidation of the surface of the silicon carbide layer 10 is suppressed. As a result, the third surface structure formed on the surface of the silicon carbide layer 10 is maintained even after the gate insulating layer 28 is formed.

In addition, in the method for manufacturing the MOSFET 100 of the first embodiment, the interface termination region 40 is formed by the third heat treatment in an atmosphere containing ammonia gas (NH₃). The interface termination region 40 is formed in an atmosphere containing ammonia gas without interface oxidation. Then, only the silicon atom in the first layer, which is the uppermost layer of the third surface structure, is bonded to the oxygen atom in the gate insulating layer 28. Therefore, the surface of the silicon carbide layer 10 after the interface termination region 40 is formed can be converted into the first surface structure with good controllability.

The MOSFET 100 of the first embodiment is an n-channel MOSFET. Therefore, when the n-type region 21 is formed on the surface of the p-well region 16 in which a channel is formed, the threshold voltage of the MOSFET 100 is reduced. In the MOSFET 100 of the first embodiment, it is possible to suppress a decrease in the threshold voltage by providing the oxygen region 22. In addition, in the MOSFET 100 of the first embodiment, high mobility is realized by providing the oxygen region 22.

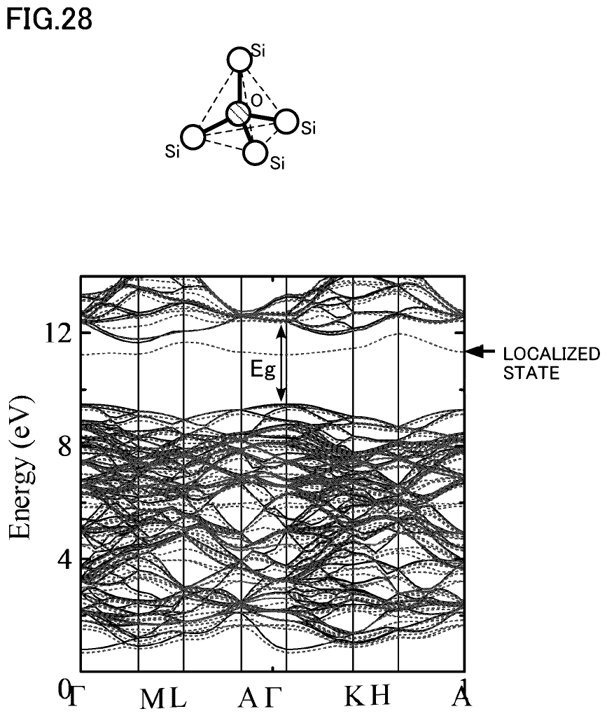

FIG. 28 is a diagram showing an electron state of the semiconductor device of the first embodiment. The electron state when one oxygen atom is present at the position (carbon site) of the carbon atom in the crystal structure of silicon carbide is obtained by first-principle calculation. That is, the electron state when the first structure containing the oxygen atom bonded to the four silicon atoms is present in the silicon carbide is obtained by the first-principle calculation.

As shown in FIG. 28, when an oxygen atom is present at the carbon site, a level is formed at a deep position away from the lower end of the conduction band. When an oxygen atom is present at the carbon site, a localized state is formed at a deep position away from the lower end of the conduction band.

The localized state is formed at a position of about 0.8 eV from the lower end of the conduction band. The energy difference between the localized state and the lower end of the conduction band is, for example, equal to or more than 0.7 eV and equal to or less than 1.0 eV.

The first structure is present in the oxygen region 22 of the MOSFET 100 of the first embodiment. Therefore, a deep level is formed in the oxygen region 22.

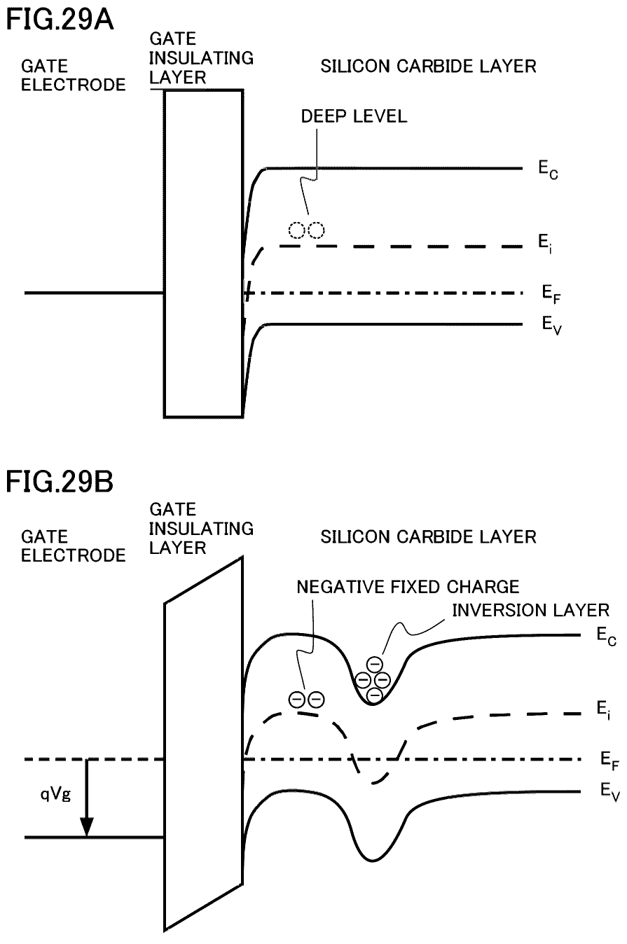

FIGS. 29A and 29B are explanatory diagrams of the function and effect of the semiconductor device of the first embodiment. FIGS. 29A and 29B are band diagrams of the MOS structure of the MOSFET 100. FIGS. 29A and 29B show a case where the silicon carbide layer is the p-well region 16. FIGS. 29A and 29B show a case where the silicon carbide layer is a p-type SiC.

FIG. 29A is a band diagram of a state in which no voltage is applied between the source electrode 34 and the gate electrode 30. FIG. 29B is a band diagram of a state in which a positive voltage (Vg in FIG. 29B) is applied to the gate electrode 30 to form an inversion layer. In addition, FIGS. 29A and 29B show an ideal case where the work function of the gate electrode 30 and the Fermi level of the silicon carbide layer 10 are equal.

As shown in FIG. 29A, in the vicinity of the interface between the silicon carbide layer 10 and the gate insulating layer 28, there is a region having a low potential since the n-type region 21 is present. For this reason, the threshold voltage of the MOS structure is lower than that in a case where the n-type region 21 is not present.

In a region deeper than the gate insulating layer 28 of the n-type region 21, there is a deep level formed by oxygen atoms entering the carbon site. When a positive voltage is applied to the gate electrode 30, the potential in the vicinity of the interface further decreases.

When the potential in the vicinity of the interface further decreases, electrons are induced, but these electrons are trapped in deep levels to form negative fixed charges as shown in FIG. 29B. Since negative fixed charges are formed in the vicinity of the interface, the potential in the vicinity of the interface increases and accordingly, the threshold voltage of the MOSFET 100 increases.

When a negative fixed charge is formed in the vicinity of the interface, the potential in the vicinity of the interface increases. Therefore, as shown in FIG. 29B, an inversion layer is formed at a deep position away from the vicinity of the interface. A so-called buried channel is formed.

When a buried channel is formed, electrons flow to a position away from the vicinity of the interface. Therefore, interfacial scattering of electrons is suppressed, and the mobility of the MOSFET 100 is increased.

As described above, according to the first embodiment, a semiconductor device having improved characteristics and a method for manufacturing the semiconductor device are realized.

### Second Embodiment

A semiconductor device of a second embodiment includes: a silicon carbide layer having a first face having an off-angle of 0° or more and 8° or less with respect to a {0001} face and a second face opposite to the first face, having a 4H-SiC crystal structure, and the silicon carbide layer including a first silicon carbide region of p-type and a second silicon carbide region of n-type provided between the first silicon carbide region and the first face and in contact with the first face; a gate electrode; a silicon oxide layer disposed between the silicon carbide layer and the gate electrode; and a region disposed between the silicon carbide layer and the silicon oxide layer and having a nitrogen concentration of 1×10²¹ cm⁻³ or more. The silicon carbide layer includes a first layer, a second layer, a third layer, a fourth layer, and a fifth layer, the first layer, the second layer, the third layer, the fourth layer, and the fifth layer are disposed from the first face towards the second face in this order, the first layer is an uppermost layer in the silicon carbide layer and in contact with the first face, a percentage of a first silicon atom among a plurality of silicon atoms present in the first layer is equal to or more than 90%, and the first silicon atom is a silicon atom occupying a site position different from a site position occupied by a silicon atom in the third layer below the first silicon atom and occupying a site position the same as a site position occupied by a silicon atom in the fifth layer below the first silicon atom. The semiconductor device of the second embodiment is different from the semiconductor device of the first embodiment in that the silicon carbide layer does not include a third silicon carbide region. Hereinafter, the description of a part of the content overlapping the first embodiment may be omitted.

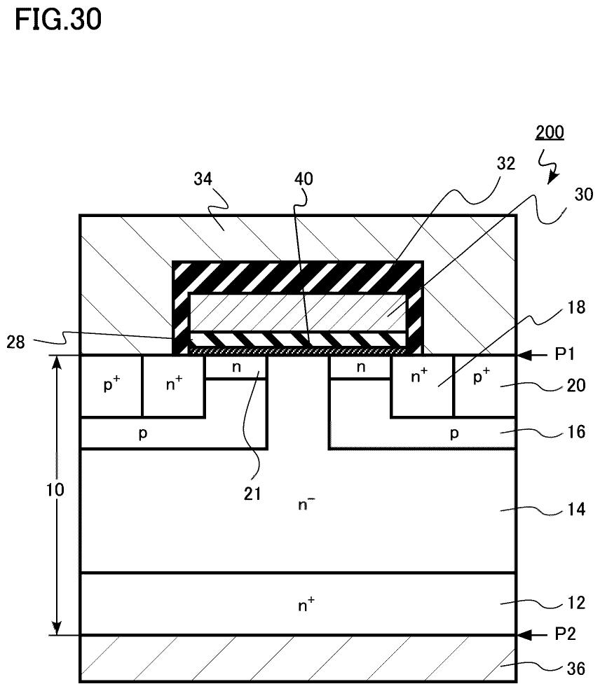

FIG. 30 is a schematic cross-sectional view of the semiconductor device of the second embodiment. The semiconductor device is a MOSFET 200. The MOSFET 200 is a DIMOSFET in which a p-well and a source region are formed by ion implantation. In addition, the MOSFET 200 is an n-channel MOSFET having electrons as carriers.

The MOSFET 200 includes a silicon carbide layer 10, a gate insulating layer 28 (silicon oxide layer), a gate electrode 30, an interlayer insulating film 32, a source electrode 34, a drain electrode 36, and an interface termination region 40 (region).

The silicon carbide layer 10 includes a drain region 12, a drift region 14, a p-well region 16 (first silicon carbide region), a source region 18, a p-well contact region 20, and an n-type region 21 (second silicon carbide region).

The silicon carbide layer 10 of the MOSFET 200 does not include an oxygen region. Since the MOSFET 200 does not include an oxygen region, the threshold voltage is lower than that of the first MOSFET 100.

For example, the MOSFET 200 can be turned off by applying a negative bias to the gate electrode 30.

As described above, according to the second embodiment, a semiconductor device having improved characteristics and a method for manufacturing the semiconductor device are realized.

### Third Embodiment

An inverter circuit and a drive device of a third embodiment are an inverter circuit and a drive device including the semiconductor device of the first embodiment.

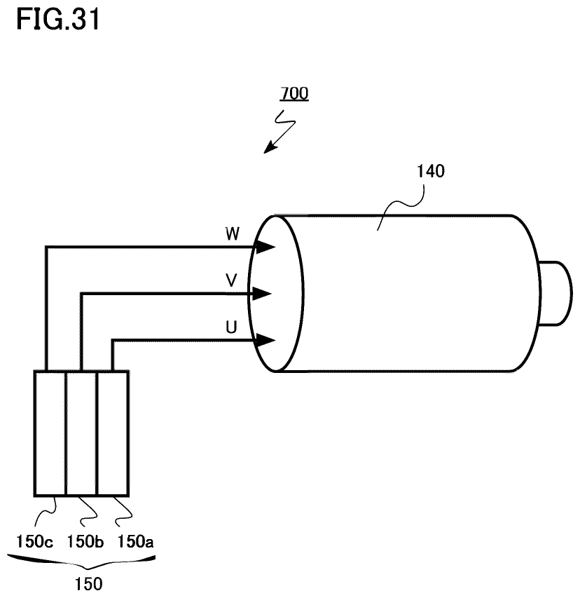

FIG. 31 is a schematic diagram of the drive device of the third embodiment. A drive device 700 includes a motor 140 and an inverter circuit 150.

The inverter circuit 150 includes three semiconductor modules 150a, 150b, and 150c having the MOSFET 100 of the first embodiment as a switching element. By connecting the three semiconductor modules 150a, 150b, and 150c in parallel to each other, a three-phase inverter circuit 150 having three AC voltage output terminals U, V, and W is realized. The motor 140 is driven by the AC voltage output from the inverter circuit 150.

According to the third embodiment, the characteristics of the inverter circuit 150 and the drive device 700 are improved by providing the MOSFET 100 with improved characteristics.

### Fourth Embodiment

A vehicle of a fourth embodiment is a vehicle including the semiconductor device of the first embodiment.

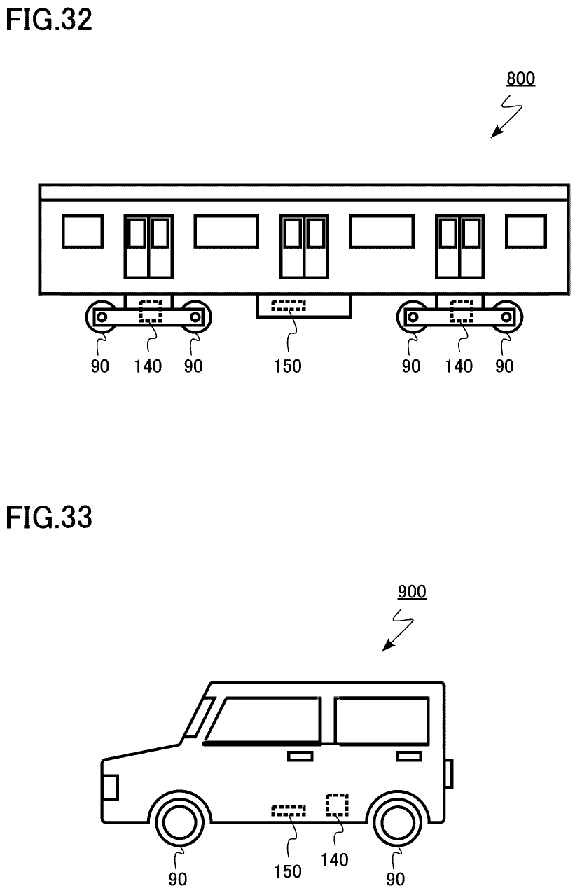

FIG. 32 is a schematic diagram of the vehicle of the fourth embodiment. A vehicle 800 of the fourth embodiment is a railroad vehicle. The vehicle 800 includes a motor 140 and an inverter circuit 150.

The inverter circuit 150 includes three semiconductor modules having the MOSFET 100 of the first embodiment as a switching element. By connecting the three semiconductor modules in parallel to each other, a three-phase inverter circuit 150 having three AC voltage output terminals U, V, and W is realized. The motor 140 is driven by the AC voltage output from the inverter circuit 150. The motor 140 rotates wheels 90 of the vehicle 800.

According to the fourth embodiment, the characteristics of the vehicle 800 are improved by providing the MOSFET 100 with improved characteristics.

### Fifth Embodiment

A vehicle of a fifth embodiment is a vehicle including the semiconductor device of the first embodiment.

FIG. 33 is a schematic diagram of the vehicle of the fifth embodiment. A vehicle 900 of the fifth embodiment is an automobile. The vehicle 900 includes a motor 140 and an inverter circuit 150.

The inverter circuit 150 includes three semiconductor modules having the MOSFET 100 of the first embodiment as a switching element. By connecting the three semiconductor modules in parallel to each other, a three-phase inverter circuit 150 having three AC voltage output terminals U, V, and W is realized.

The motor 140 is driven by the AC voltage output from the inverter circuit 150. The motor 140 rotates wheels 90 of the vehicle 900.

According to the fifth embodiment, the characteristics of the vehicle 900 are improved by providing the MOSFET 100 with improved characteristics.

### Sixth Embodiment

An elevator of a sixth embodiment is an elevator including the semiconductor device of the first embodiment.

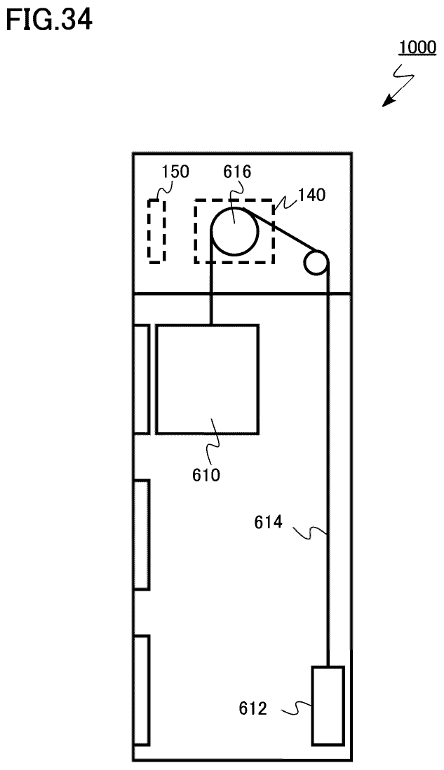

FIG. 34 is a schematic diagram of the elevator of the sixth embodiment. An elevator 1000 of the sixth embodiment includes a car 610, a counterweight 612, a wire rope 614, a hoisting machine 616, a motor 140, and an inverter circuit 150.

The inverter circuit 150 includes three semiconductor modules having the MOSFET 100 of the first embodiment as a switching element. By connecting the three semiconductor modules in parallel to each other, a three-phase inverter circuit 150 having three AC voltage output terminals U, V, and W is realized.

The motor 140 is driven by the AC voltage output from the inverter circuit 150. The hoisting machine 616 is rotated by the motor 140, and the car 610 is moved up and down.

According to the sixth embodiment, the characteristics of the elevator 1000 are improved by providing the MOSFET 100 with improved characteristics.

In the first and second embodiments, the n-channel MOSFET has been described as an example, but embodiments can also be applied to an n-channel insulated gate bipolar transistor (IGBT).

In the first embodiment, the oxygen region 22 is provided between the p-well region 16 and the first face P1. However, the oxygen region can be provided in other regions, for example, between the drift region 14 and the first face P1.

In addition, in the third to sixth embodiments, the configuration including the MOSFET 100 of the first embodiment has been described as an example. However, a configuration including the MOSFET 200 of the second embodiment is also possible.

In addition, in the fourth to sixth embodiments, the cases where the semiconductor devices of the embodiments are applied to a vehicle or an elevator have been described as examples, but the semiconductor devices of the embodiments can also be applied to, for example, a power conditioner of a photovoltaic power generation system.

While certain embodiments have been described, these embodiments have been presented by way of example only, and are not intended to limit the scope of the inventions. Indeed, the semiconductor device, the semiconductor device manufacturing method, the inverter circuit, the drive device, the vehicle, and the elevator described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
a silicon carbide layer having a first face having an off-angle of 00 or more and 8° or less with respect to a {0001} face and a second face opposite to the first face, having a 4H-SiC crystal structure, and the silicon carbide layer including a first silicon carbide region of p-type and a second silicon carbide region of n-type provided between the first silicon carbide region and the first face and in contact with the first face;
a gate electrode;
a silicon oxide layer disposed between the silicon carbide layer and the gate electrode; and
a region disposed between the silicon carbide layer and the silicon oxide layer and having a nitrogen concentration of 1×10²¹ cm⁻³ or more,
wherein the silicon carbide layer includes a first layer, a second layer, a third layer, a fourth layer, and a fifth layer,
the first layer, the second layer, the third layer, the fourth layer, and the fifth layer are disposed from the first face towards the second face in this order, the first layer is an uppermost layer in the silicon carbide layer and in contact with the first face,
a percentage of a first silicon atom among a plurality of silicon atoms present in the first layer is equal to or more than 90%, and
the first silicon atom is a silicon atom occupying a site position different from a site position occupied by a silicon atom in the third layer below the first silicon atom and occupying a site position the same as a site position occupied by a silicon atom in the fifth layer below the first silicon atom.

2. The semiconductor device according to claim 1,
wherein silicon atoms other than the first silicon atom among the plurality of silicon atoms include a second silicon atom or a third silicon atom,
a site position occupied by the second silicon atom is the same as a site position occupied by a silicon atom in the third layer below the second silicon atom and the same as a site position occupied by a silicon atom in the fifth layer below the second silicon atom, and
a site position occupied by the third silicon atom is different from a site position occupied by a silicon atom in the third layer below the third silicon atom and different from a site position occupied by a silicon atom in the fifth layer below the third silicon atom.

3. An inverter circuit comprising the semiconductor device according to claim 1.

4. A drive device comprising the semiconductor device according to claim 1.

5. A vehicle comprising the semiconductor device according to claim 1.

6. An elevator comprising the semiconductor device according to claim 1.

7. A semiconductor device manufacturing method, comprising:
ion-implanting aluminum (Al) into a predetermined region of a silicon carbide layer with a surface having an off-angle of 0° or more and 8° or less with respect to a {0001} face;
ion-implanting at least one element of nitrogen (N) or phosphorus (P) into the predetermined region;
ion-implanting silicon (Si) into the predetermined region;
ion-implanting oxygen (O) into the predetermined region;
ion-implanting carbon (C) into the predetermined region;
forming a carbon film on the silicon carbide layer;
performing a first heat treatment at 1600° C. or higher;
removing the carbon film;
performing a second heat treatment at 1100° C. or higher in an atmosphere containing argon or hydrogen;
forming a silicon oxide film on the silicon carbide layer;
performing a third heat treatment in an atmosphere containing nitrogen; and
forming a gate electrode on the silicon oxide film.

8. The semiconductor device manufacturing method according to claim 7,
wherein the atmosphere containing nitrogen is an atmosphere containing ammonia gas.

9. The semiconductor device manufacturing method according to claim 7,
wherein the silicon oxide film is formed by a vapor deposition method.

10. The semiconductor device manufacturing method according to claim 7,
wherein after the ion-implanting the at least one element, the ion-implanting silicon (Si), the ion-implanting oxygen (O), and the ion-implanting carbon (C), and before the performing the first heat treatment,
a depth at which the at least one element concentration is maximized is smaller than a depth at which the oxygen concentration is maximized, a depth at which the silicon concentration is maximized, and a depth at which the carbon concentration is maximized, and
the depth at which the oxygen concentration is maximized and the depth at which the silicon concentration is maximized are smaller than the depth at which the carbon concentration is maximized.

11. The semiconductor device manufacturing method according to claim 10,
wherein after the ion-implanting the at least one element, the ion-implanting silicon (Si), the ion-implanting oxygen (O), and the ion-implanting carbon (C), and before the performing the first heat treatment,
a silicon ion implantation profile covers an entire oxygen ion implantation profile.
